(19) United States
(12) Patent Application Publication
(10) Pub. No.: US 2025/0331197 A1
(43) Pub. Date: Oct. 23, 2025

(54) MAGNETORESISTIVE MEMORY DEVICE CONTAINING SELF-ALIGNED SELECTOR ELEMENTS AND METHODS FOR FORMING THE SAME

(71) Applicant: SANDISK TECHNOLOGIES LLC, ADDISON, TX (US)

(72) Inventors: Lei WAN, San Jose, CA (US); Neil ROBERTSON, Palo Alto, CA (US); Jordan KATINE, Mountain View, CA (US)

(21) Appl. No.: 18/643,202

(22) Filed: Apr. 23, 2024

(51) Int. Cl. H10B 61/00

(52) U.S. Cl. CPC H10B 61/10

(57) ABSTRACT

A method of forming a magnetoresistive memory array includes forming a stack structure including a one-dimensional array of first conductive lines laterally extending along a first horizontal direction, an array of magnetic tunnel junction stacks each containing a reference layer, a tunnel barrier layer, and a free layer located over the first conductive lines, and a two-dimensional array of sacrificial pillar structures located over the array of magnetic tunnel junction stacks, forming a dielectric matrix layer laterally surrounding the two-dimensional array of sacrificial pillar structures, forming a two-dimensional array of via cavities by removing the two-dimensional array of sacrificial pillar structures selective to the dielectric matrix layer, forming selector elements at least within volumes of the two-dimensional array of via cavities, and forming a one-dimensional array of second conductive lines laterally extending along a second horizontal direction over the selector elements.

### FIELD

The present disclosure relates generally to the field of memory devices and specifically to a magnetoresistive random access memory (MRAM) memory device including self-aligned selector elements and methods of making the same.

### BACKGROUND

The MRAM device can store information employing the difference in electrical resistance of a first configuration in which a ferromagnetic free layer has a magnetization direction that is parallel to the magnetization of a ferromagnetic reference layer and a second configuration in which the free layer has a magnetization direction that is antiparallel to the magnetization of the reference layer. Programming of the MRAM device includes flipping of the direction of the magnetization of the free layer employing an external power source.

### SUMMARY

According to an aspect of the present disclosure, a method of forming a magnetoresistive memory array includes forming a stack structure including a one-dimensional array of first conductive lines laterally extending along a first horizontal direction, an array of magnetic tunnel junction stacks each containing a reference layer, a tunnel barrier layer, and a free layer located over the first conductive lines, and a two-dimensional array of sacrificial pillar structures located over the array of magnetic tunnel junction stacks, forming a dielectric matrix layer laterally surrounding the two-dimensional array of sacrificial pillar structures, forming a two-dimensional array of via cavities by removing the two-dimensional array of sacrificial pillar structures selective to the dielectric matrix layer, forming selector elements at least within volumes of the two-dimensional array of via cavities, and forming a one-dimensional array of second conductive lines laterally extending along a second horizontal direction over the selector elements.

According to another aspect of the present disclosure, a magnetoresistive memory array is provided, which comprises: a one-dimensional array of first conductive lines laterally extending along a first horizontal direction and overlying a substrate; an array of magnetic tunnel junction stacks each comprising a magnetic polarizer layer, a reference layer, a tunnel barrier layer, at least one free layer; a two-dimensional array of lower electrodes overlying the array of magnetic tunnel junction stacks; an array of selector elements overlying the two-dimensional array of lower electrodes, wherein each of the selector elements has a vertical sidewall having a bottom periphery that coincides with a top periphery of a tapered sidewall of an underlying lower electrode among the two-dimensional array of lower electrodes; a dielectric matrix layer laterally surrounding the two-dimensional array of sacrificial pillar structures and the two-dimensional array of lower electrodes; and a one-dimensional array of second conductive lines laterally extending along a second horizontal direction and contacting at least one selector element within the array of selector elements.

### BRIEF DESCRIPTION OF THE DRAWINGS

FIG. 1A is a first vertical cross-sectional view of an exemplary structure after formation of driver circuits, metal interconnect structures embedded in lower-level dielectric material layers, and first conductive lines according to an embodiment of the present disclosure.

FIG. 1B is a second vertical cross-sectional view of the exemplary structure along the vertical plane B-B′ of FIG. 1A. The vertical plane A-A′ is the cut plane for the first vertical cross-sectional view of FIG. 1A.

FIG. 2A is a first vertical cross-sectional view of a region of the exemplary structure in a first configuration after formation of a layer stack including a continuous magnetic polarizer layer, a continuous reference layer, a continuous tunnel barrier layer, and a continuous free layer; a lower electrode layer; and a sacrificial pillar material layer according to a first embodiment of the present disclosure.

FIG. 2B is a second vertical cross-sectional view of a region of the exemplary structure in the first configuration along the vertical plane B-B′ of FIG. 2A. The vertical plane A-A′ is the cut plane for the first vertical cross-sectional view of FIG. 2A.

FIG. 3A is a first vertical cross-sectional view of a region of the exemplary structure in the first configuration after patterning the sacrificial pillar material layer into a two-dimensional array of sacrificial pillar structures employing a two-dimensional array of etch mask portions according to a first embodiment of the present disclosure.

FIG. 3B is a second vertical cross-sectional view of a region of the exemplary structure in the first configuration along the vertical plane B-B′ of FIG. 3A. The vertical plane A-A′ is the cut plane for the first vertical cross-sectional view of FIG. 3A.

FIG. 3C is a top-down view of a region of the exemplary structure in the first configuration of FIGS. 3A and 3B.

FIG. 4A is a first vertical cross-sectional view of a region of the exemplary structure in the first configuration after patterning the lower electrode layer into a two-dimensional array of lower electrodes and patterning the layer stack into an array of magnetic tunnel junction stacks according to the first embodiment of the present disclosure.

FIG. 4B is a second vertical cross-sectional view of a region of the exemplary structure in the first configuration along the vertical plane B-B′ of FIG. 4A. The vertical plane A-A′ is the cut plane for the first vertical cross-sectional view of FIG. 4A.

FIG. 5A is a first vertical cross-sectional view of a region of the exemplary structure in the first configuration after formation of a dielectric matrix layer according to the first embodiment of the present disclosure.

FIG. 5B is a second vertical cross-sectional view of a region of the exemplary structure in the first configuration along the vertical plane B-B′ of FIG. 5A. The vertical plane A-A′ is the cut plane for the first vertical cross-sectional view of FIG. 5A.

FIG. 6A is a first vertical cross-sectional view of a region of the exemplary structure in the first configuration after planarization of the dielectric matrix layer according to the first embodiment of the present disclosure.

FIG. 6B is a second vertical cross-sectional view of a region of the exemplary structure in the first configuration along the vertical plane B-B′ of FIG. 6A. The vertical plane A-A′ is the cut plane for the first vertical cross-sectional view of FIG. 6A.

FIG. 7A is a first vertical cross-sectional view of a region of the exemplary structure in the first configuration after removal of the two-dimensional array of sacrificial pillar structures and formation of a two-dimensional array of via cavities according to the first embodiment of the present disclosure.

FIG. 7B is a second vertical cross-sectional view of a region of the exemplary structure in the first configuration along the vertical plane B-B′ of FIG. 7A. The vertical plane A-A′ is the cut plane for the first vertical cross-sectional view of FIG. 7A.

FIG. 8A is a first vertical cross-sectional view of a region of the exemplary structure in the first configuration after performing a first nucleation inhibitor adhesion step according to the first embodiment of the present disclosure.

FIG. 8B is a second vertical cross-sectional view of a region of the exemplary structure in the first configuration along the vertical plane B-B′ of FIG. 8A. The vertical plane A-A′ is the cut plane for the first vertical cross-sectional view of FIG. 8A.

FIG. 9A is a first vertical cross-sectional view of a region of the exemplary structure in the first configuration after performing a first precursor adhesion step according to the first embodiment of the present disclosure.

FIG. 9B is a second vertical cross-sectional view of a region of the exemplary structure in the first configuration along the vertical plane B-B′ of FIG. 9A. The vertical plane A-A′ is the cut plane for the first vertical cross-sectional view of FIG. 9A.

FIG. 10A is a first vertical cross-sectional view of a region of the exemplary structure in the first configuration after performing a first oxygen plasma treatment step according to the first embodiment of the present disclosure.

FIG. 10B is a second vertical cross-sectional view of a region of the exemplary structure in the first configuration along the vertical plane B-B′ of FIG. 10A. The vertical plane A-A′ is the cut plane for the first vertical cross-sectional view of FIG. 10A.

FIG. 11A is a first vertical cross-sectional view of a region of the exemplary structure in the first configuration after performing a second nucleation inhibitor adhesion step according to the first embodiment of the present disclosure.

FIG. 11B is a second vertical cross-sectional view of a region of the exemplary structure in the first configuration along the vertical plane B-B′ of FIG. 11A. The vertical plane A-A′ is the cut plane for the first vertical cross-sectional view of FIG. 11A.

FIG. 12A is a first vertical cross-sectional view of a region of the exemplary structure in the first configuration after performing a second precursor adhesion step according to the first embodiment of the present disclosure.

FIG. 12B is a second vertical cross-sectional view of a region of the exemplary structure in the first configuration along the vertical plane B-B′ of FIG. 12A. The vertical plane A-A′ is the cut plane for the first vertical cross-sectional view of FIG. 12A.

FIG. 13A is a first vertical cross-sectional view of a region of the exemplary structure in the first configuration after performing a second oxygen plasma treatment step according to the first embodiment of the present disclosure.

FIG. 13B is a second vertical cross-sectional view of a region of the exemplary structure in the first configuration along the vertical plane B-B′ of FIG. 13A. The vertical plane A-A′ is the cut plane for the first vertical cross-sectional view of FIG. 13A.

FIG. 14A is a first vertical cross-sectional view of a region of the exemplary structure in the first configuration after formation of selector elements through repetition of a set of processing steps including a nucleation inhibitor adhesion step, a precursor adhesion step, and an oxygen plasma treatment step according to the first embodiment of the present disclosure.

FIG. 14B is a second vertical cross-sectional view of a region of the exemplary structure in the first configuration along the vertical plane B-B′ of FIG. 14A. The vertical plane A-A′ is the cut plane for the first vertical cross-sectional view of FIG. 14A.

FIG. 15A is a first vertical cross-sectional view of the exemplary structure in the first configuration after formation of second conductive lines and upper-level metal interconnect structures and bonding pads according to embodiments of the present disclosure.

FIG. 15B is a second vertical cross-sectional view of the exemplary structure along the vertical plane B-B′ of FIG. 15A. The vertical plane A-A′ is the cut plane for the first vertical cross-sectional view of FIG. 15A.

FIG. 16A is a first vertical cross-sectional view of a region of the exemplary structure in a second configuration after removal of the two-dimensional array of sacrificial pillar structures and formation of a two-dimensional array of via cavities according to a second embodiment of the present disclosure.

FIG. 16B is a second vertical cross-sectional view of a region of the exemplary structure in the first configuration along the vertical plane B-B′ of FIG. 16A. The vertical plane A-A′ is the cut plane for the first vertical cross-sectional view of FIG. 16A.

FIG. 17A is a first vertical cross-sectional view of a region of the exemplary structure in a second configuration after formation of a selector material layer according to a second embodiment of the present disclosure.

FIG. 17B is a second vertical cross-sectional view of a region of the exemplary structure in the second configuration along the vertical plane B-B′ of FIG. 17A. The vertical plane A-A′ is the cut plane for the first vertical cross-sectional view of FIG. 17A.

FIG. 18A is a first vertical cross-sectional view of a region of the exemplary structure in the second configuration after formation of a two-dimensional array of selector elements according to the second embodiment of the present disclosure.

FIG. 18B is a second vertical cross-sectional view of a region of the exemplary structure in the second configuration along the vertical plane B-B′ of FIG. 18A. The vertical plane A-A′ is the cut plane for the first vertical cross-sectional view of FIG. 18A.

FIG. 19A is a first vertical cross-sectional view of a region of the exemplary structure in the second configuration after formation of second conductive lines and upper-level dielectric material layers according to the second embodiment of the present disclosure.

FIG. 19B is a second vertical cross-sectional view of a region of the exemplary structure in the second configuration along the vertical plane B-B′ of FIG. 19A. The vertical plane A-A′ is the cut plane for the first vertical cross-sectional view of FIG. 19A.

FIG. 20A is a first vertical cross-sectional view of a region of the exemplary structure in a third configuration after formation of a selector material layer and a second metallic material layer according to a third embodiment of the present disclosure.

FIG. 20B is a second vertical cross-sectional view of a region of the exemplary structure in the third configuration along the vertical plane B-B′ of FIG. 20A. The vertical plane A-A′ is the cut plane for the first vertical cross-sectional view of FIG. 20A.

FIG. 21A is a first vertical cross-sectional view of a region of the exemplary structure in the third configuration after formation of second conductive lines and a one-dimensional array of selector elements according to the third embodiment of the present disclosure.

FIG. 21B is a second vertical cross-sectional view of a region of the exemplary structure in the third configuration along the vertical plane B-B′ of FIG. 21A. The vertical plane A-A′ is the cut plane for the first vertical cross-sectional view of FIG. 21A.

FIG. 22A is a first vertical cross-sectional view of a region of the exemplary structure in the third configuration after formation of upper-level dielectric material layers according to the third embodiment of the present disclosure.

FIG. 22B is a second vertical cross-sectional view of a region of the exemplary structure in the third configuration along the vertical plane B-B′ of FIG. 22A. The vertical plane A-A′ is the cut plane for the first vertical cross-sectional view of FIG. 22A.

FIG. 23A is a first vertical cross-sectional view of an exemplary structure in a fourth configuration after formation of driver circuits and metal interconnect structures embedded in lower-level dielectric material layers according to a fourth embodiment of the present disclosure.

FIG. 23B is a second vertical cross-sectional view of the exemplary structure along the vertical plane B-B′ of FIG. 23A. The vertical plane A-A′ is the cut plane for the first vertical cross-sectional view of FIG. 23A.

FIG. 24A is a first vertical cross-sectional view of a region of the exemplary structure in the fourth configuration after formation of a layer stack including a continuous magnetic polarizer layer, a continuous reference layer, a continuous tunnel barrier layer, and a continuous free layer; and a lower electrode layer according to a fourth embodiment of the present disclosure.

FIG. 24B is a second vertical cross-sectional view of a region of the exemplary structure in the fourth configuration along the vertical plane B-B′ of FIG. 24A. The vertical plane A-A′ is the cut plane for the first vertical cross-sectional view of FIG. 24A.

FIG. 25A is a first vertical cross-sectional view of a region of the exemplary structure in the fourth configuration after patterning the lower electrode layer into a one-dimensional array of lower electrodes employing a one-dimensional array of etch mask portions according to a fourth embodiment of the present disclosure.

FIG. 25B is a second vertical cross-sectional view of a region of the exemplary structure in the fourth configuration along the vertical plane B-B′ of FIG. 25A. The vertical plane A-A′ is the cut plane for the first vertical cross-sectional view of FIG. 25A.

FIG. 25C is a top-down view of a region of the exemplary structure in the fourth configuration of FIGS. 25A and 25B.

FIG. 26A is a first vertical cross-sectional view of a region of the exemplary structure in the fourth configuration after patterning the layer stack into a one-dimensional array of magnetic tunnel junction stacks and after patterning the first metallic material layer into first conductive lines according to the fourth embodiment of the present disclosure.

FIG. 26B is a second vertical cross-sectional view of a region of the exemplary structure in the fourth configuration along the vertical plane B-B′ of FIG. 26A. The vertical plane A-A′ is the cut plane for the first vertical cross-sectional view of FIG. 26A.

FIG. 27A is a first vertical cross-sectional view of a region of the exemplary structure in the fourth configuration after formation of insulating rails and forming a sacrificial pillar material layer according to the fourth embodiment of the present disclosure.

FIG. 27B is a second vertical cross-sectional view of a region of the exemplary structure in the fourth configuration along the vertical plane B-B′ of FIG. 27A. The vertical plane A-A′ is the cut plane for the first vertical cross-sectional view of FIG. 27A.

FIG. 28A is a first vertical cross-sectional view of a region of the exemplary structure in the fourth configuration after patterning the sacrificial pillar material layer into a two-dimensional array of sacrificial pillar structures according to the fourth embodiment of the present disclosure.

FIG. 28B is a second vertical cross-sectional view of a region of the exemplary structure in the fourth configuration along the vertical plane B-B′ of FIG. 28A. The vertical plane A-A′ is the cut plane for the first vertical cross-sectional view of FIG. 28A.

FIG. 28C is a top-down view of a region of the exemplary structure in the fourth configuration of FIGS. 28A and 28B.

FIG. 29A is a first vertical cross-sectional view of a region of the exemplary structure in the fourth configuration after vertically recessing the insulating rails and unmasked portions of the lower electrodes, dielectric capping layers, and free layers according to the fourth embodiment of the present disclosure.

FIG. 29B is a second vertical cross-sectional view of a region of the exemplary structure in the fourth configuration along the vertical plane B-B′ of FIG. 29A. The vertical plane A-A′ is the cut plane for the first vertical cross-sectional view of FIG. 29A.

FIG. 30A is a first vertical cross-sectional view of a region of the exemplary structure in the fourth configuration after formation of a dielectric matrix layer according to the fourth embodiment of the present disclosure.

FIG. 30B is a second vertical cross-sectional view of a region of the exemplary structure in the fourth configuration along the vertical plane B-B′ of FIG. 30A. The vertical plane A-A′ is the cut plane for the first vertical cross-sectional view of FIG. 30A.

FIG. 31A is a first vertical cross-sectional view of a region of the exemplary structure in the fourth configuration after planarization of the dielectric matrix layer according to the fourth embodiment of the present disclosure.

FIG. 31B is a second vertical cross-sectional view of a region of the exemplary structure in the fourth configuration along the vertical plane B-B′ of FIG. 31A. The vertical plane A-A′ is the cut plane for the first vertical cross-sectional view of FIG. 31A.

FIG. 32A is a first vertical cross-sectional view of a region of the exemplary structure in the fourth configuration after removal of the two-dimensional array of sacrificial pillar structures and formation of a two-dimensional array of via cavities according to the fourth embodiment of the present disclosure.

FIG. 32B is a second vertical cross-sectional view of a region of the exemplary structure in the fourth configuration along the vertical plane B-B′ of FIG. 32A. The vertical plane A-A′ is the cut plane for the first vertical cross-sectional view of FIG. 32A.

FIG. 33A is a first vertical cross-sectional view of a region of the exemplary structure in the fourth configuration after formation of a two-dimensional array of selector elements according to the fourth embodiment of the present disclosure.

FIG. 33B is a second vertical cross-sectional view of a region of the exemplary structure in the fourth configuration along the vertical plane B-B′ of FIG. 33A. The vertical plane A-A′ is the cut plane for the first vertical cross-sectional view of FIG. 33A.

FIG. 34A is a first vertical cross-sectional view of a region of the exemplary structure in the fourth configuration after formation of second conductive lines and upper-level dielectric material layers according to the fourth embodiment of the present disclosure.

FIG. 34B is a second vertical cross-sectional view of a region of the exemplary structure in the fourth configuration along the vertical plane B-B′ of FIG. 34A. The vertical plane A-A′ is the cut plane for the first vertical cross-sectional view of FIG. 34A.

### DETAILED DESCRIPTION

Fabrication of spin transfer torque (STT) magnetoresistive random access memory (MRAM) cells containing magnetic tunnel junction (MTJ) and selector element pillars presents various challenges. One of such challenges is the damage to the sidewalls of the pillar containing the MTJ and the selector element, such as ovonic threshold switch (OTS) selector element, caused by etch processes used to form the pillar, such as ion beam etching (IBE) and reactive ion etching (RIE). As discussed above, embodiments of the present disclosure are directed to a memory device including self-aligned selector elements which avoid or reduce etch damage to the pillar sidewalls during formation of the selector elements of the MRAM cells arranged in a cross-point array configuration.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Embodiments of the present disclosure provide methods for fabricating MRAM devices including an MTJ and selector pillar cross-point arrays without etching the selector layer, thus eliminating the risk of etching-related damage to the pillar sidewalls during the selector formation. In one embodiment, MTJ layers and a sacrificial pillar material layer (which functions as a hard mask layer and comprises a sacrificial hard mask material such as diamond like carbon) may be deposited, followed by patterning of the sacrificial pillar material layer into a two-dimensional array of sacrificial pillar structures and patterning of the MTJ layers into an array of MTJ stacks (e.g., pillars). A two-dimensional array of sacrificial pillar structures and the array of MTJ stacks are subsequently encapsulated with a dielectric matrix layer. A planarization process can be performed to expose top surfaces of the two-dimensional array of sacrificial pillar structures, which is selectively removed to form self-aligned via cavities directly above the MTJ stacks. The via cavities can be subsequently filled with selector elements. In some embodiment, the via cavities may be employed to facilitate the deposition of ovonic threshold switch pillars in a self-aligned manner, effectively forming etch-free ovonic threshold switch (OTS) selector elements. In some embodiments, area-selective atomic layer deposition processes may be employed for ovonic threshold switch deposition, allowing for precise control over the thickness and composition of the ovonic threshold switch layers, thereby ensuring high device performance and stability.

Alternatively, a selector material layer may be deposited in a manner that fills the via cavities and overlies the dielectric matrix layer. The selector material layer may be patterned in a manner in which only portions of the selector material layer overlying the dielectric matrix layer are subjected to etching, while portions of the selector material layer filling the via cavities are not exposed to an etch environment. Each selector element may comprise a horizontally-extending portion overlying the dielectric matrix layer and downward-protruding pillar portions filling the via cavities and self-aligned to the magnetic tunnel junction stacks. The downward-protruding pillar portions include etch-free ovonic threshold switch pillars.

The embodiments of the present disclosure avoid or reduce the risk of physical and chemical etch damage to the selector pillar sidewalls by depositing the selector pillars into via cavities without etching of the sidewalls of the selector pillars. Thus, embodiments of the present disclosure overcome etching-induced damage and fabrication complexity of prior art selector pillar manufacturing processes. Embodiments of the present disclosure can enhance the performance, the reliability, and the manufacturability of cross-point MRAM arrays.

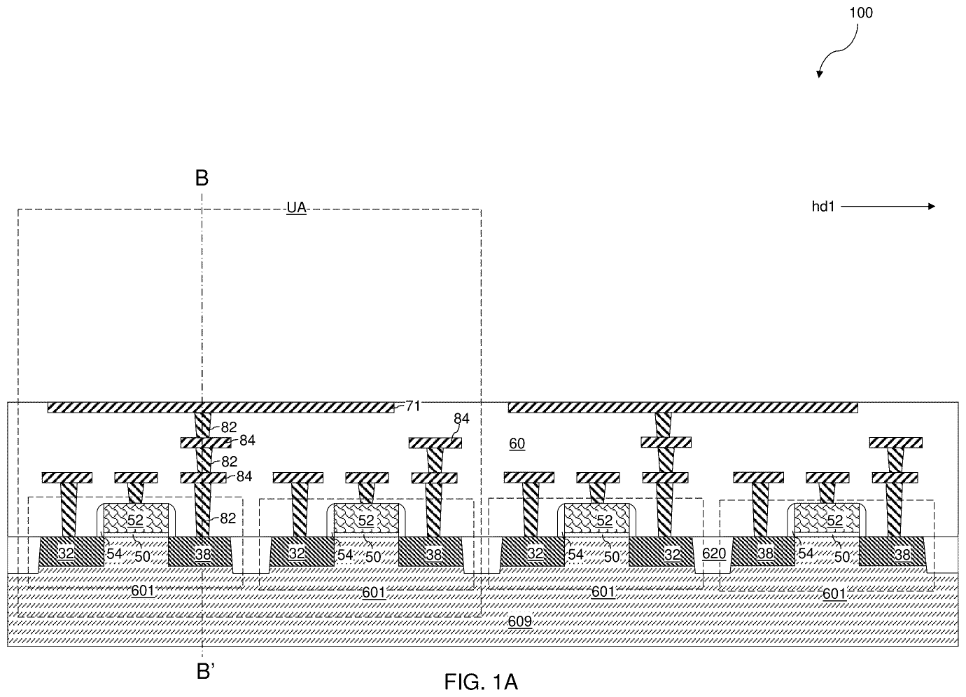

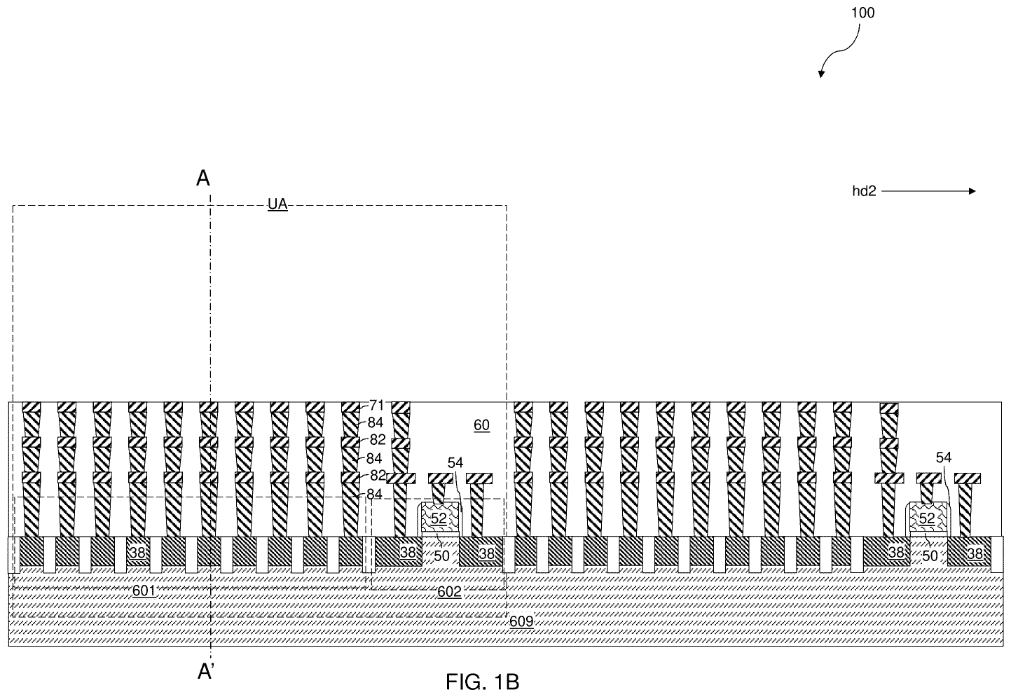

According to FIGS. 1A and 1B, an exemplary structure 100 according to an embodiment of the present disclosure is illustrated. The exemplary structure 100 may comprise a substrate, such as a semiconductor substrate 609, various driver circuits (601, 602) for driving access lines of MRAM arrays to be subsequently formed, lower-level metal interconnect structures (82, 84) embedded in lower-level dielectric material layers 60, and first conductive lines 71 laterally extending along a first horizontal direction hd1 and embedded in a topmost dielectric material layer among the lower-level dielectric material layers 60.

As used herein, access lines collectively refer to conductive lines that are electrically connected to a respective row of or to a respective column of MRAM cells. In case the MRAM cells comprise portions of respective MRAM pillar structures, the access lines may contact end surfaces (such as bottom surfaces or top surfaces) of a respective row of MRAM pillar structures or a respective column of MRAM pillar structures. Depending on the configurations of the driver circuits, access lines may function as word lines or bit lines. Thus, access lines as used herein collective refer to word lines and bit lines. The access lines may comprise an electrically conductive material, such W, Cu, Ru, Ta, TiN, etc. The first conductive lines 71 function as first access lines for the MRAM array to be subsequently formed.

The various driver circuits (601, 602) comprise field effect transistors and other suitable additional semiconductor devices (not expressly shown) located on, in and/or over the semiconductor substrate 609. The field effect transistors may comprise source regions 32, drain regions 38, gate dielectrics 50, gate electrodes 52, and optional dielectric gate sidewall spacers 54. The additional semiconductor device may comprise any type of semiconductor devices known in the art, such as diodes, resistors, capacitors, etc.

The various driver circuits (601, 602) may comprise, for example, first driver circuits 601 configured to drive the first conductive lines 71, second driver circuits 602 configured to drive second access lines to be subsequently formed in the exemplary structure 100. The various driver circuits (601, 602) can be configured to enable programming and reading (sensing) operations of the MRAM cells to be subsequently formed in the exemplary structure 100. The various driver circuits (601, 602) may comprise word line drivers and bit line drivers. The types of circuitries employed for the various driver circuits (601, 602) may be suitably selected based on the type of MRAM cells to be employed in the memory arrays that are subsequently formed in the exemplary structure 100. For example, if the first conductive lines 71 comprise word lines, then the first driver circuits 601 may comprise word line drivers (i.e., word line switching circuits) for the word lines of the MRAM cells of the exemplary structure 100, and second driver circuits 602 may comprise bit line drivers (i.e., bit line switching circuits) for the bit lines of MRAM cells of the exemplary structure 100.

The lower-level metal interconnect structures (82, 84) comprise metal via structures 82 and conductive lines 84. The lower-level metal interconnect structures (82, 84) may comprise any suitable metal or metal alloy, such as copper or copper alloy. The lower-level metal interconnect structures (82, 84) are configured to provide electrical connections between the electrical nodes (e.g., transistor source regions 32 and drain regions 38) of the various driver circuits (601, 602) and the access lines (e.g., word lines or bit lines) of MRAM cells to be subsequently formed.

The lower-level dielectric material layers 60 can include any interlayer dielectric (ILD) material known in the art, which include, for example, undoped silicate glass (i.e., silicon oxide), doped silicate glasses, porous or non-porous silicate glass, dielectric metal oxide materials, silico oxynitride, silicon carbide nitride, etc. The lower-level metal interconnect structures (82, 84) can be formed in the lower-level dielectric material layers 60 employing patterning methods known in the art, which include, but are not limited to, patterning metal layers into the interconnect structures followed by deposition of the lower-level dielectric material layers 60, single damascene metal deposition method in openings in lower-level dielectric material layers 60, dual damascene metal deposition methods in multi-level openings in the lower-level dielectric material layers 60, etc.

A one-dimensional array of first conductive lines 71 are formed within a first dielectric material layer (which may be a topmost dielectric material layer of the lower-level dielectric material layers 60). The first conductive lines 71 comprise conductive lines that laterally extend along the first horizontal direction (e.g., word line direction) hd1 with a uniform pitch along a second horizontal direction (e.g., bit line direction) hd2 that may be perpendicular to the first horizontal direction hd1. The pitch of the first conductive lines 71 along the second horizontal direction hd2 may be about twice the width of each first conductive line 71. The length of the first conductive lines 71 along the first horizontal direction hd1 is determined by the lateral dimensions of the MRAM cells to be subsequently formed and by a total number of the MRAM cells to be connected to each first conductive line 71. In an illustrative example, the total number of the MRAM cells to be connected to a first conductive line 71 may be in a range from 2 to 2¹⁴, although a greater number may also be employed.

The structures formed over the semiconductor substrate 609 may be periodic along the first horizontal direction hd1 and along the second horizontal direction hd2. In this case, the exemplary structure may comprise a two-dimensional periodic repetitions of a unit pattern. The area of each unit pattern is herein referred to as a unit area UA.

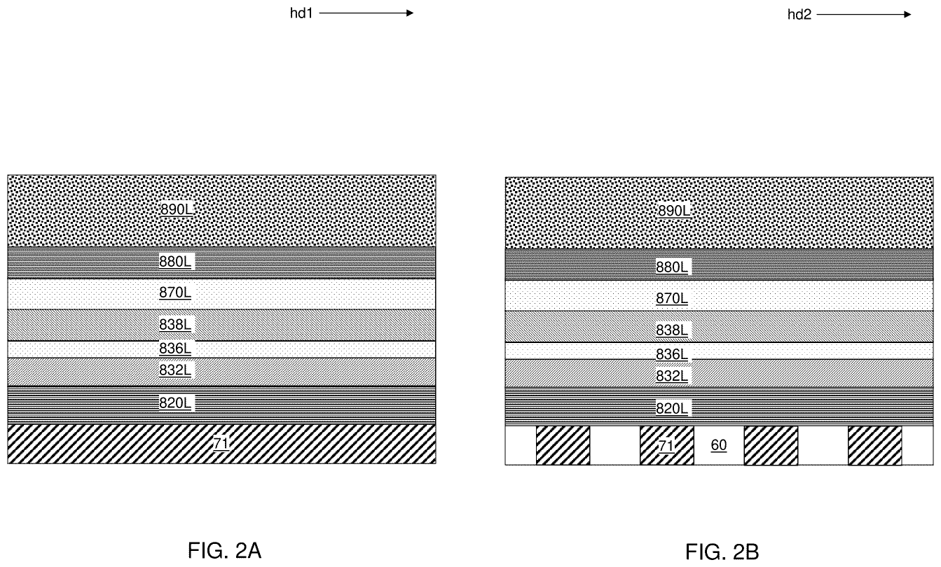

Referring to FIGS. 2A and 2B, a layer stack (820L, 832L, 836L, 838L, 870L) including a continuous magnetic polarizer layer 820L, a continuous reference layer 832L, a continuous tunnel barrier layer 836L, a continuous free layer 838L, and an optional continuous dielectric capping layer 870L can be sequentially deposited over the first conductive lines 71 and a first dielectric material layer (such as the topmost layer of the lower-level dielectric material layers 60). A lower electrode layer 880L and a sacrificial pillar material layer 890L are sequentially deposited over the layer stack (820L, 832L, 836L, 838L, 870L).

The continuous magnetic polarizer layer 820L can be any material layer or a material layer stack that can function as a hard magnetization layer, i.e., a magnetic material layer having a stable magnetization direction. In one embodiment, the continuous magnetic polarizer layer 820L has a magnetization direction that is antiparallel to the magnetization direction of the continuous reference layer 832L, and an antiferromagnetic coupling layer (not illustrated for clarity) may be provided between the continuous magnetic polarizer layer 820L and the continuous reference layer 832L that provides antiferromagnetic coupling therebetween. In one embodiment, the continuous magnetic polarizer layer 820L comprises a ferromagnetic multilayer structure including a superlattice, an exchange-bias-inducing antiferromagnetic layer, or a stack of at least one ferromagnetic material layer and at least one antiferromagnetic layer. Alternatively, the continuous magnetic polarizer layer 820L may comprise a synthetic antiferromagnetic (SAF) structure. Generally, the continuous magnetic polarizer layer 820L may comprise any magnetic structure that can pin the magnetization direction of the continuous reference layer 832L.

In a non-limiting illustrative example, the continuous magnetic polarizer layer 820L may comprise a superlattice of cobalt layers and platinum layers. The number repetitions of a combination of a cobalt layer and a platinum layer may be in a range from 2 to 10, such as from 3 to 6, although lesser and greater number of repetitions may also be employed. In an illustrative example, the cobalt layers may have a respective thickness of 0.2 nm to 0.5 nm, and the platinum layers may have a respective thickness of about 0.1 nm to 0.3 nm. It is understood that a material layer having a thickness that is less than the thickness of a monolayer refers to a discontinuous layer having a fractional coverage that is equal to the ratio of the thickness of the material layer to the thickness of the monolayer.

If an antiferromagnetic coupling layer is employed, the antiferromagnetic coupling layer (not illustrated) has a material composition and a thickness that provide antiferromagnetic coupling between the continuous magnetic polarizer layer 820L and the continuous reference layer 832L. In one embodiment, the antiferromagnetic coupling layer (not illustrated) can include ruthenium or iridium, and can have a thickness in a range from 0.3 nm to 0.8 nm.

Each of the continuous reference layer 832L and continuous free layer 838L include a ferromagnetic material, such as CoFeB, CoFe, Co, Ni, NiFe, or a combination thereof. The thickness of the continuous free layer 838L may be in a range from 1 nm to 3 nm, although lesser and greater thicknesses may also be employed. The thickness of the continuous reference layer 832L may be in a range from 2.5 nm to 10 nm, although lesser and greater thicknesses may also be employed.

Each of the continuous reference layer 832L and continuous free layer 838L may be independently deposited using physical vapor deposition (PVD) or atomic layer deposition (ALD). The continuous tunnel barrier layer 836L includes a dielectric tunnel barrier material. such as magnesium oxide (MgO). In one embodiment, the thickness of the continuous tunnel barrier layer 836L may be in a range from 0.7 nm to 2.4 nm, although lesser and greater thickness may also be employed. The continuous tunnel barrier layer 836L can be deposited using physical vapor deposition or atomic layer deposition to provide uniform thickness and high-quality coverage.

The continuous dielectric capping layer 870L includes a dielectric material such as magnesium oxide (MgO), aluminum oxide (Al₂O₃) or silicon nitride (Si₃N₄). The thickness of the continuous dielectric capping layer 870L may range from 0.5 nm to 1 nm, although lesser and greater thicknesses may also be employed. The continuous dielectric capping layer 870L can be deposited using chemical vapor deposition (CVD) or atomic layer deposition (ALD).

In one embodiment, the lower electrode layer 880L includes a nonmagnetic metallic material that can be used as an electrically conductive electrode. For example, the lower electrode layer 880L may include Ru, Ti, Ta, W, Mo, TiN, TaN, WN, MON, or a combination thereof. The thickness of the lower electrode layer 880L may range from 5 nm to 50 nm. The lower electrode layer 880L may be formed by physical vapor deposition (PVD). In another embodiment, the lower electrode layer 880L may comprise a bilayer of a carbon nitride sublayer and an overlying sacrificial sublayer. The sacrificial sublayer may comprise any material which can function as an etch stop during patterning of the sacrificial pillar material layer 890L.

The sacrificial pillar material layer 890L includes a material that can function as an etch mask material for the layer stack (820L, 832L, 836L, 838L, 870L) during a subsequent etch process, and can be subsequently removed selective to a dielectric material (such as silicon oxide) of a dielectric matrix layer to be subsequently formed. For example, the sacrificial pillar material layer 890L may comprise a carbon-based ashable etch mask material, such as diamond-like carbon (DLC) or amorphous carbon. The thickness of the sacrificial pillar material layer 890L may range from 40 nm to 300 nm, although lesser and greater thicknesses may also be employed. The sacrificial pillar material layer 890L can be deposited using chemical vapor deposition (CVD) or sputtering.

In one embodiment, the sacrificial pillar material layer 890L may comprise and/or may consist essentially of diamond-like carbon. The use of diamond-like carbon as a hard mask material provides a high ion milling resistance, and thus, allows for the fabrication of denser MRAM arrays with minimized shadowing effects. Thus, the use of diamond-like carbon as the hard mask material permits the use of high lithographic resolution for patterning the layer stack (820L, 832L, 836L, 838L, 870L), and facilitates the formation of self-aligned via cavities for formation of selector elements therein, thereby reducing fabrication complexity and improving process yield.

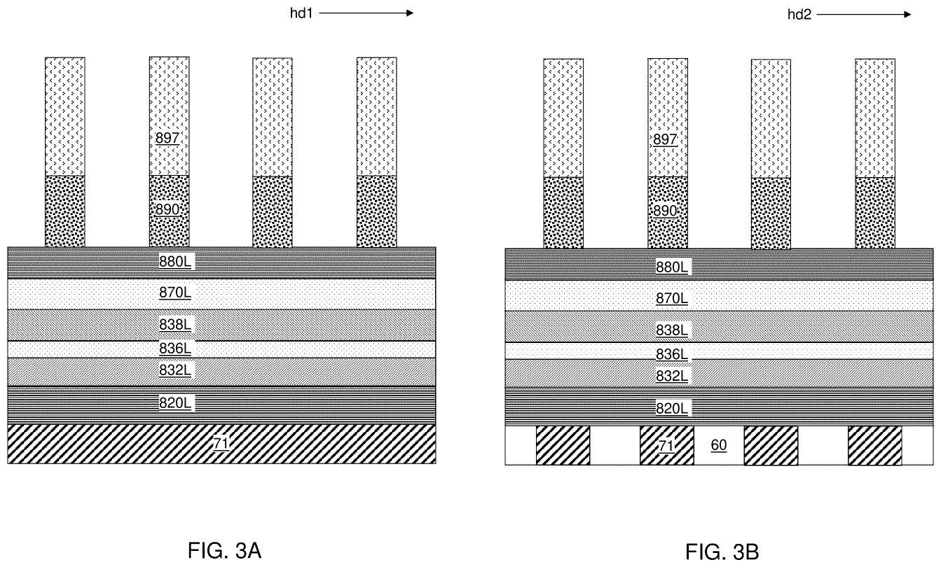

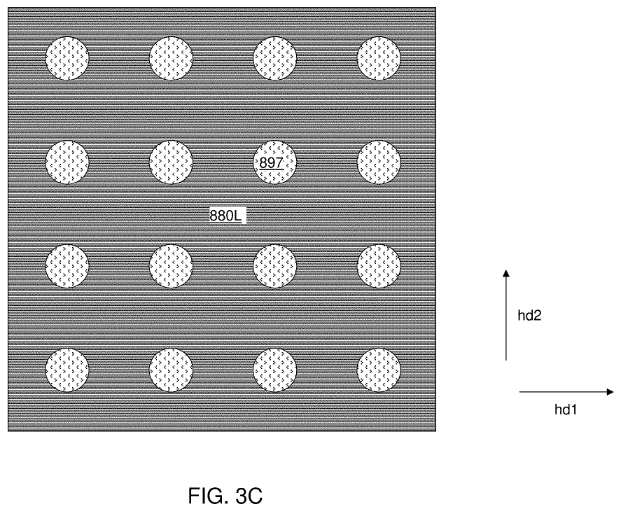

Referring to FIGS. 3A-3C, a two-dimensional array of etch mask portions can be formed over the sacrificial pillar material layer 890L. In one embodiment, the two-dimensional array of etch mask portions may comprise a patterned photoresist layer 897, which can be formed by applying a blanket photoresist material layer over the sacrificial pillar material layer 890L and by lithographically patterning the blanket photoresist material layer, i.e., by performing a lithographic exposure process and a lithographic development process. The patterned photoresist layer 897 may comprise a two-dimensional periodic array of discrete patterned photoresist material portions. These portions may have cylindrical shapes. In one embodiment, the two-dimensional periodic array may comprise a two-dimensional rectangular array. Each of the discrete patterned photoresist material portions may have a respective circular horizontal cross-sectional shape having a diameter in a range from 20 nm to 100 nm, although lesser and greater dimensions may also be employed, or other suitable shapes, such as polygonal (e.g. rectangular, etc.) or oval shapes.

An anisotropic etch process, such as a reactive ion etch process, can be performed to pattern the sacrificial pillar material layer 890L into a two-dimensional array of sacrificial pillar structures 890 employing the two-dimensional array of etch mask portions (such as the patterned photoresist layer 897) as an etch mask. If the sacrificial pillar material layer 890L comprises diamond-like carbon, the reactive ion etch process may employ an oxygen-based etch chemistry. The anisotropic etch process transfers the pattern in the two-dimensional array of etch mask portions (such as the patterned photoresist layer 897) through the sacrificial pillar material layer 890L. Remaining patterned portions of the sacrificial pillar material layer 890L comprise a two-dimensional array of sacrificial pillar structures 890, each of which may have a respective cylindrical shape. The sacrificial pillar structures 890 may have circular horizontal cross-sectional shapes or other suitable shapes, such as polygonal (e.g. rectangular, etc.) or oval horizontal cross-sectional shapes. If the lower electrode layer 880L comprises a bilayer of a carbon nitride sublayer and an overlying sacrificial sublayer, then the sacrificial sublayer functions as an etch stop during the etching of the sacrificial pillar structures 890.

The two-dimensional array of etch mask portions (such as the patterned photoresist layer 897) can be subsequently removed, for example, by ashing. The process conditions for the ashing process can be selected such that the patterned photoresist layer 897 is removed without removing the two-dimensional array of sacrificial pillar structures 890. For example, the ashing temperature may be selected to be higher than the decomposition temperature of the material of the patterned photoresist layer 897, and is lower than the decomposition temperature of the material of the two-dimensional array of sacrificial pillar structures 890 (which may be diamond-like carbon).

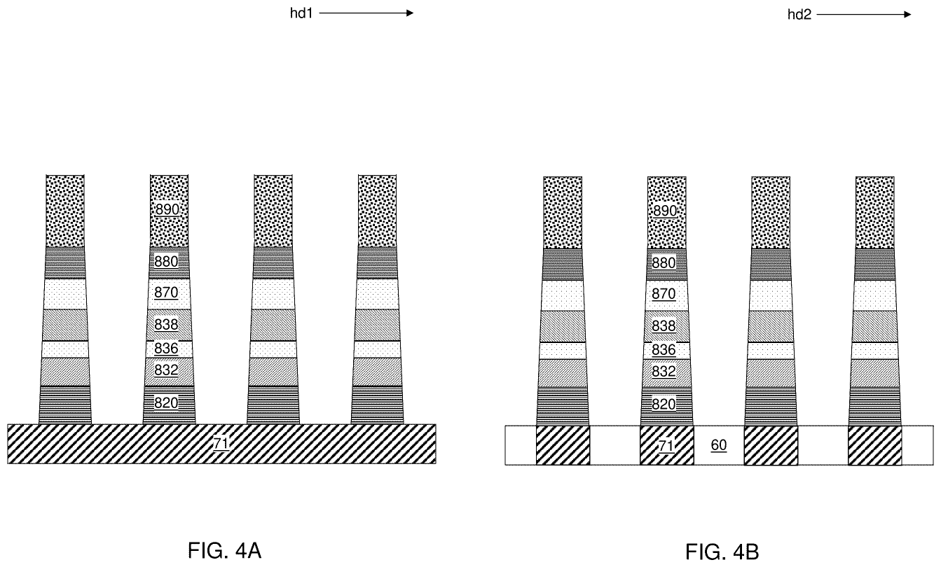

Referring to FIGS. 4A and 4B, the lower electrode layer 880L and the layer stack (820L, 832L, 836L, 838L, 870L) can be patterned by performing an etch process that etches unmasked portions of the lower electrode layer 880L and the layer stack (820L, 832L, 836L, 838L, 870L) employing the two-dimensional array of sacrificial pillar structures 890 as an etch mask. In one embodiment, the etch process may comprise an ion beam etch (IBE) process. The ion beam etch process employs energetic ions, such as argon ions, accelerated by an electric field to energies typically between 500 to 1000 electron volts (eV). The ion beam etch process removes material by physically sputtering atoms from the unmasked portions of the lower electrode layer 880L and the layer stack (820L, 832L, 836L, 838L, 870L). The two-dimensional array of sacrificial pillar structures 890 may be collaterally etched to a lesser degree during the ion beam etch process. Generally, the sidewalls of the two-dimensional array of sacrificial pillar structures 890 remain vertical, while tapered sidewalls are formed in patterned remaining portions of the lower electrode layer 880L and the layer stack (820L, 832L, 836L, 838L, 870L). Remaining patterned portions of the lower electrode layer 880L comprise a two-dimensional array of lower electrodes 880. Remaining patterned portions of the layer stack (820L, 832L, 836L, 838L, 870L) comprise an array of magnetic tunnel junction (MTJ) stacks (e.g., MTJ pillars) (820, 832, 836, 838, 870).

Each magnetic tunnel junction stack (820, 832, 836, 838, 870) may comprise a magnetic polarizer layer 820 which is a patterned portion of the continuous magnetic polarizer layer 820L, a reference layer 832 which is a patterned portion of the continuous reference layer 832L, a tunnel barrier layer 836 which is a patterned portion of the continuous tunnel barrier layer 836L, a free layer 838 which is a patterned portion of the continuous free layer 838L, and a dielectric capping layer 870 which is a patterned portion of the continuous dielectric capping layer 870L. The thickness of the sacrificial pillar structures 890 after the etch process may be in a range from 5 nm to 100 nm, such as from 15 nm to 50 nm, although lesser and greater thicknesses may also be employed.

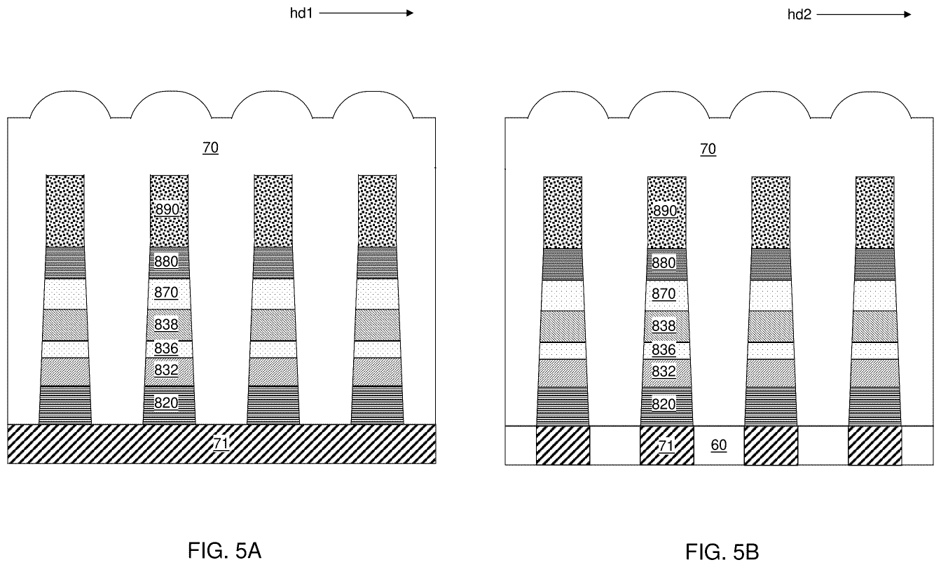

Referring to FIGS. 5A and 5B, a planarizable dielectric fill material, such as silicon oxide, silicon nitride, silicon carbonitride, or a dielectric metal oxide can be conformally deposited in the gaps within the two-dimensional array of magnetic tunnel junction stacks (820, 832, 836, 838, 870) and the two-dimensional array of sacrificial pillar structures 890, and over the two-dimensional array of sacrificial pillar structures 890 to form a dielectric matrix layer 70. In one embodiment, the dielectric matrix layer 70 may comprise and/or may consist essentially of silicon oxide. The dielectric matrix layer 70 laterally surrounds the two-dimensional array of magnetic tunnel junction stacks (820, 832, 836, 838, 870) and the two-dimensional array of sacrificial pillar structures 890 and may have a contoured top surface overlying the horizontal plane including the top surfaces of the two-dimensional array of sacrificial pillar structures 890.

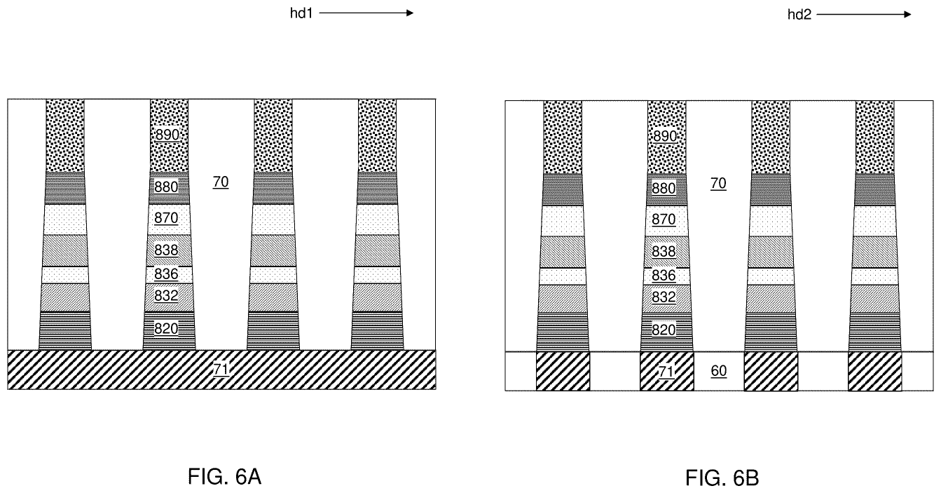

Referring to FIGS. 6A and 6B, a chemical mechanical polishing (CMP) process can be performed to remove portions of the dielectric fill material of the dielectric matrix layer 70 from above the horizontal plane including the top surfaces of the two-dimensional array of sacrificial pillar structures 890. After the CMP process, the top surface of the dielectric matrix layer 70 can be a planar surface located within the same horizontal plane as the top surfaces of the two-dimensional array of sacrificial pillar structures 890.

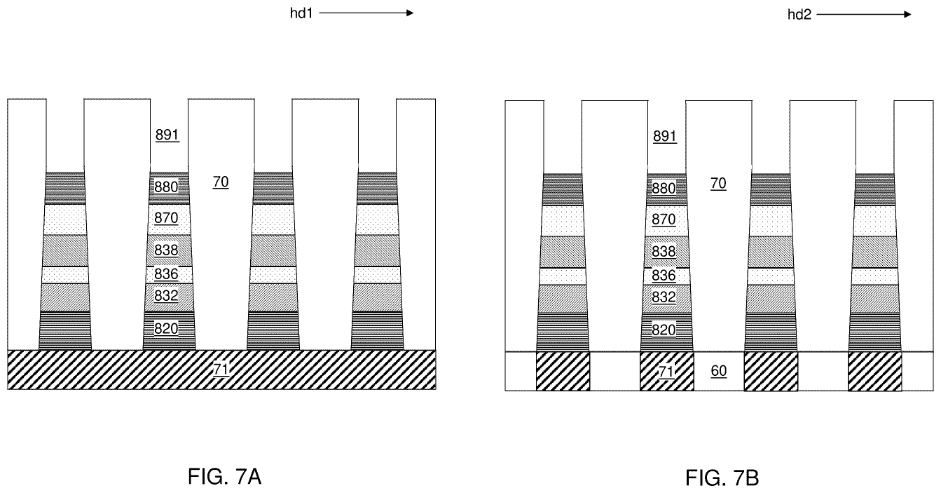

Referring to FIGS. 7A and 7B, the material of the two-dimensional array of sacrificial pillar structures 890 can be removed selective to the materials of the dielectric matrix layer 70 and the lower electrodes 880. The sacrificial pillar structures 890 can be removed by a selective etching process (e.g., selective reactive ion etching) or by a high temperature ashing process. A two-dimensional array of via cavities 891 can be formed in the volumes from which the two-dimensional array of sacrificial pillar structures 890 is removed. Generally, the two-dimensional array of via cavities 891 can be formed by removing the two-dimensional array of sacrificial pillar structures 890 selective to the dielectric matrix layer 70 and selective to the array of magnetic tunnel junction stacks (820, 832, 836, 838, 870). A top surface of a lower electrode (e.g., metal electrode) 880 can be physically exposed at the bottom of each via cavity 891. The depth of each via cavity 891 may be in a range from 5 nm to 100 nm, such as from 15 nm to 50 nm, although lesser and greater thicknesses may also be employed. In the alternative embodiment in which the lower electrode layer 880L comprises a bilayer of a carbon nitride sublayer and an overlying sacrificial sublayer, the overlying sacrificial sublayer is removed by selective dry or wet etching, such that the lower electrode 880 comprises a carbon nitride electrode.

Subsequently, a selector material, such as an ovonic threshold switch (OTS) material, can be deposited in the via cavities 891. In some embodiments, a selective atomic layer deposition (ALD) process may be employed to deposit the selector material only on top surfaces of the lower electrodes 880 while preventing growth of the selector material from dielectric surfaces such as the surfaces of the dielectric matrix layer 70. In some embodiments, nucleation inhibitor molecules may be used in the selective atomic layer deposition process as will be discussed below.

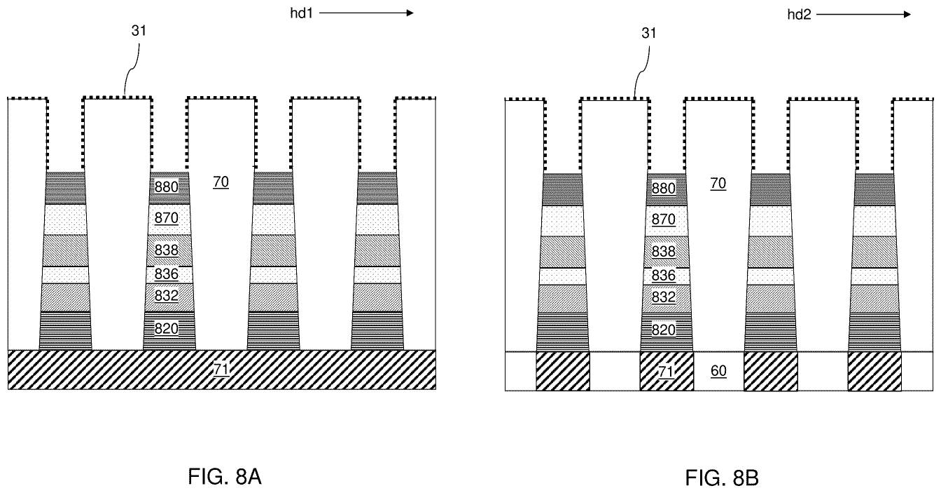

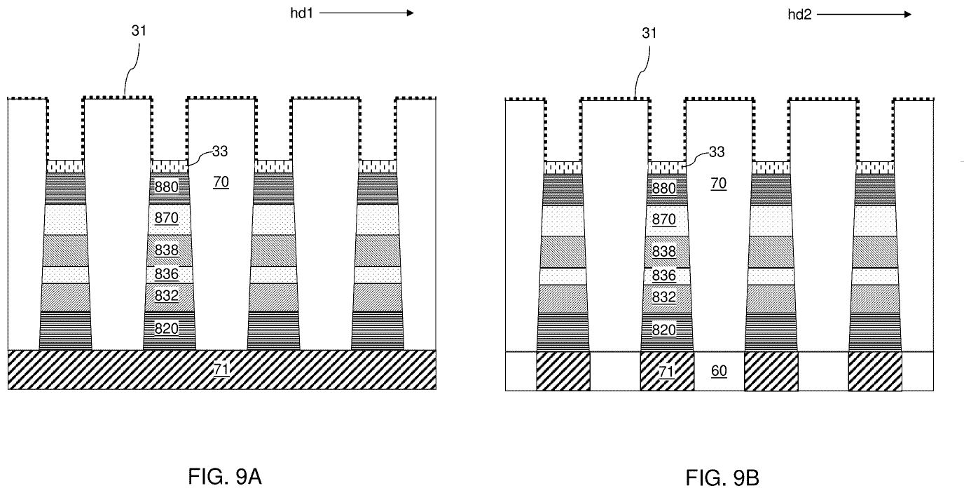

Referring to FIGS. 8A and 8B, a first nucleation inhibitor adhesion step can be performed. Specifically, a layer 31 of nucleation inhibitor molecules can be nucleated on physically exposed surfaces of the dielectric matrix layer 70 while adhesion of the nucleation inhibitor molecules on the top surfaces of the lower electrodes 880 is suppressed. The nucleation inhibitor molecules selectively modify surface properties of the physically exposed dielectric surfaces of the dielectric matrix layer 70 to prevent subsequent nucleation of a precursor gas employed to deposit a selector material. The nucleation inhibitor molecules comprise self-assembled monolayers (SAMs) or functional polymer chains that exhibit strong binding affinity towards dielectric surfaces (such as silicon dioxide surfaces) and do not exhibit affinity to metallic surfaces. For example, functionated silanes may be employed as effective nucleation inhibitors. Nonlimiting examples of the functionated silanes include dodecyltrimethoxysilane and hexamethyldisilazane. The nucleation inhibitor molecules react with silanol groups on silicon oxide is surfaces to form a chemically modified layer that repels selector precursor gases, which may be ovonic threshold switch material precursor gases. The inhibitor adhesion process step can be performed in a vapor phase or from a liquid solution. Referring to FIGS. 9A and 9B, a first precursor adhesion step can be performed. Specifically, one or more monolayers 33 of an ovonic threshold switch material precursor gas can be adsorbed to the top surfaces of the lower electrodes 880 while adhesion of the one or more monolayers 33 of the ovonic threshold switch material precursor gas over the layer 31 of nucleation inhibitor molecules is suppressed. The ovonic threshold switch material precursor gases are selected based on their reactivity with the electrode material and their non-reactivity with the modified dielectric surfaces, i.e., the surfaces of the dielectric matrix layer 70 as modified by formation of the layer 31 of nucleation inhibitor molecules. Nonlimiting examples of such precursor gases include trichlorigermane (HGeCl₃), Ge(N(Si(CH₃)₃)₂)₂, antimony (III) ethoxide (Sb(OC₂H₅)₃), dimethyl telluride (CH₃)₂Te, dimethyl selenide (CH₃)₂Se, dimethylsilyl telluride ((CH₃)Si)₂Te, dimethylsilyl selenide ((CH₃)Si)₂Se, etc. to form germanium antimony selenide, germanium antimony selenide, germanium antimony selenide telluride, or other ovonic threshold switch material. Additional precursor gases (e.g., As and/or Al precursor cases) capable of forming chalcogenide ovonic threshold semiconductor materials may also be employed. In some embodiments, ovonic threshold switch material compositions can be provided on the physically exposed surfaces of the nonmetallic metal plates 880 by flowing multiple precursor gases sequentially or concurrently.

Suppression of nucleation of the one or more monolayers 33 of the at least one ovonic threshold switch material precursor gas provides the benefit of composition control at interfaces with the dielectric matrix layer 70. By preventing or reducing nucleation of the selector material on the surfaces of the dielectric matrix layer 70, the material composition of the selector material to be subsequently formed can be controlled with the less variations.

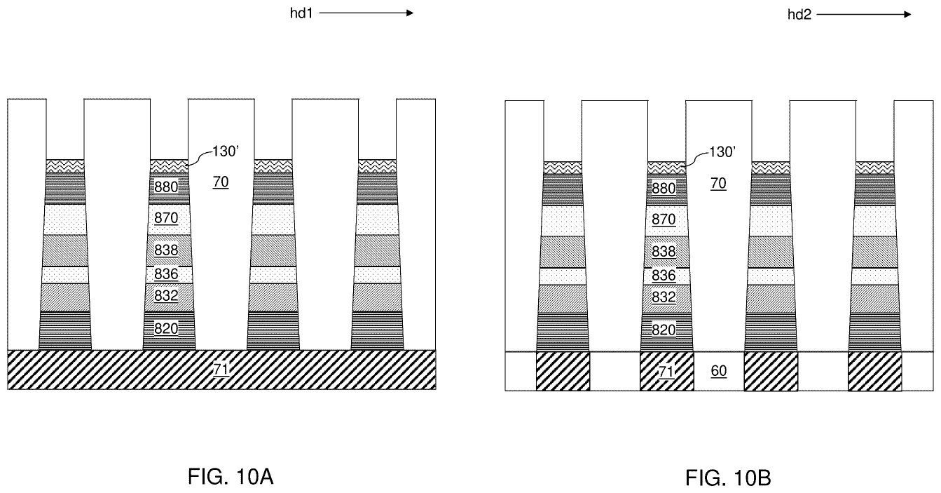

Referring to FIGS. 10A and 10B, a first oxygen plasma treatment step can be performed. The first oxygen plasma treatment step removes ligands from the adsorbed one or more monolayers 33 of the ovonic threshold switch material precursor gas. The first oxygen plasma treatment step also collaterally removes the layer 31 of nucleation inhibitor molecules from the surfaces of the dielectric matrix layer 70. Remaining atoms of the adsorbed one or more monolayers 33 of the ovonic threshold switch material precursor gas form a layer 130′ of the selector material. The thickness of the layer 130′ of the selector material may be in a range from 0.1 nm to 1.5 nm, such as from 0.3 nm to 0.8 nm, although lesser and greater thicknesses may also be employed. Generally, at least a portion of the selector elements can be formed by performing a selective deposition process that deposits a selector material of the selector elements on the top surfaces of the lower electrodes 880 while suppressing nucleation of the selector material over the layer 31 of nucleation inhibitor molecules.

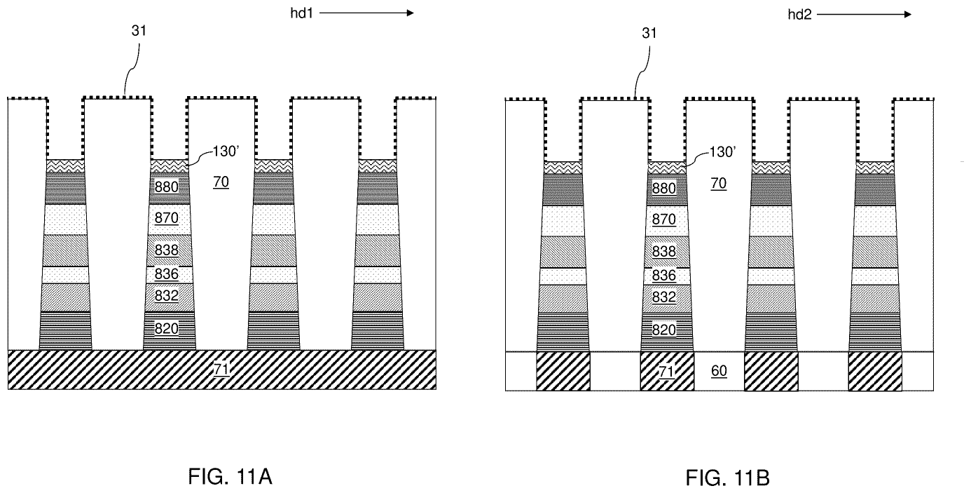

Referring to FIGS. 11A and 11B, a second nucleation inhibitor adhesion step can be performed in the same manner as the first nucleation inhibitor adhesion step described with reference to FIGS. 8A and 8B. During the second nucleation inhibitor adhesion step, the layer 31 of nucleation inhibitor molecules can be nucleated on physically exposed surfaces of the dielectric matrix layer 70 while adhesion of the nucleation inhibitor molecules on the top surfaces of the layer 130′ of the selector material is suppressed.

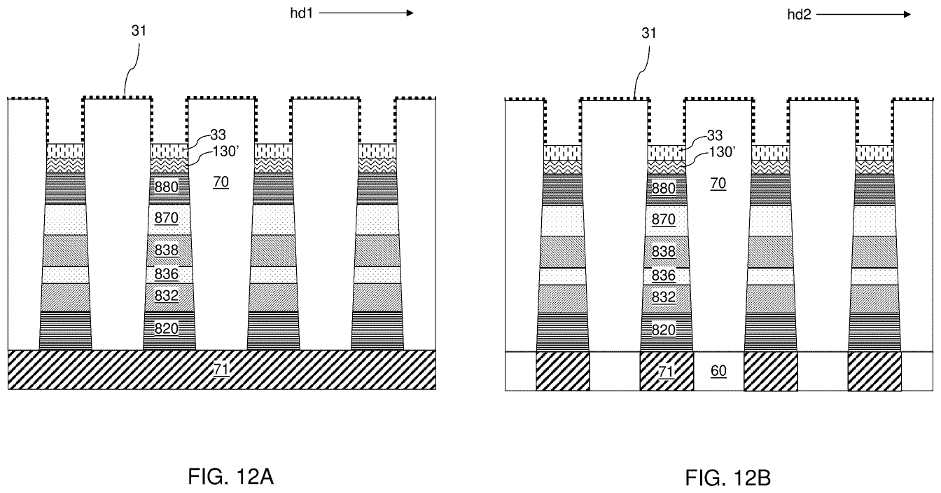

Referring to FIGS. 12A and 12B, a second precursor adhesion step can be performed in the same manner as the first precursor adhesion step described with reference to FIGS. 9A and 9B. During the second precursor adhesion step, one or more monolayers 33 of an ovonic threshold switch material precursor gas can be adsorbed to the top surfaces of the layer 130′ of the selector material while adhesion of the one or more monolayers 33 of the ovonic threshold switch material precursor gas over the layer 31 of nucleation inhibitor molecules is suppressed.

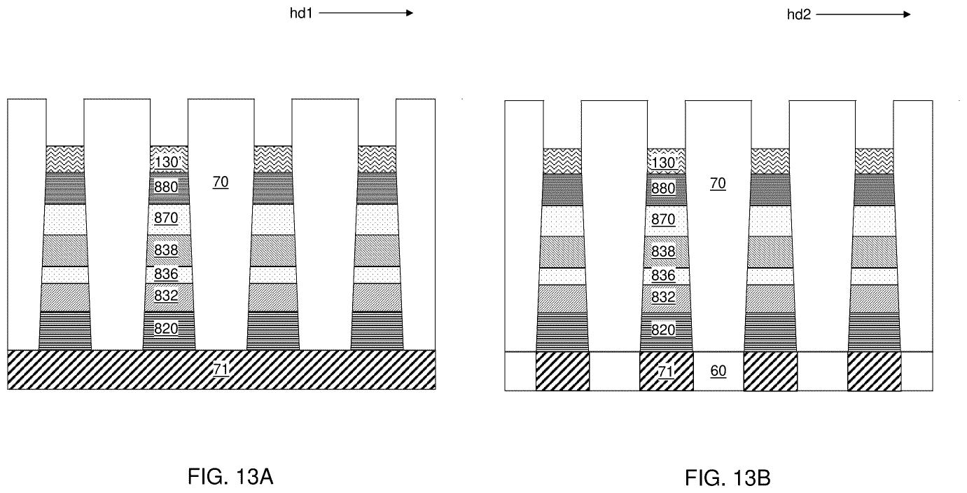

Referring to FIGS. 13A and 13B, a second oxygen plasma treatment step can be performed in the same manner as the first oxygen plasma treatment step described with reference to FIGS. 10A and 10B. During the second oxygen plasma treatment step, ligands from the adsorbed one or more monolayers 33 of the ovonic threshold switch material precursor gas are removed, and remaining atoms of the adsorbed one or more monolayers 33 of the ovonic threshold switch material precursor gas are incorporated into the layer 130′ of the selector material, thereby increasing the thickness of the layer 130′ of the selector material. The incremental thickness of the layer 130′ of the selector material may be in a range from 0.1 nm to 1.5 nm, such as from 0.3 nm to 0.8 nm, although lesser and greater incremental thicknesses may also be employed.

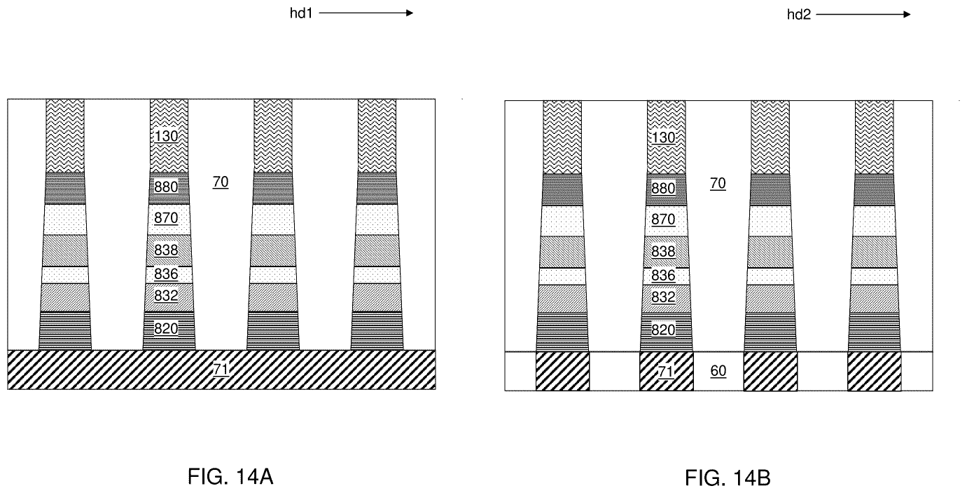

Referring to FIGS. 14A and 14B, the processing steps described with reference to FIGS. 11A-13B may be repeated as many times as necessary to fill in the entire volume of the via cavities 891. In this case, the number of repetitions of the processing steps of FIGS. 14A and 14B may be determined based on the target thickness of the selector elements 130 that are formed in the via cavities 891. In one embodiment, top surfaces of the selector elements 130 may be formed at or close to the horizontal plane including the top surface of the dielectric matrix layer 70. Alternatively, the top surfaces of the selector elements 130 may be formed below or above the horizontal plane including the top surface of the dielectric matrix layer 70. If the top surfaces of the selector elements 130 are formed above the horizontal plane including the top surface of the dielectric matrix layer 70, each of the selector elements 130 may have a top portion having a mushroom-shaped vertical cross-sectional profile.

Alternatively, lower portions of the selector elements 130 may be formed by repeating the processing steps of FIGS. 14A and 14B, and upper portions of the selector elements 130 may be formed employing a deposition process that provides a higher deposition rate, such as a physical vapor deposition process. In this case, a planarization process, such as a chemical mechanical polishing process and/or a recess etch process, may be employed to remove portions of the deposited selector material from above the horizontal plane including the top surface of the dielectric matrix layer 70.

In summary, selector elements 130 may be formed at least within volumes of the two-dimensional array of via cavities 891. At least a portion of the selector elements 130 can be formed by performing a selective deposition process that deposits a selector material of the selector elements on the top surfaces of the lower electrodes 880 while suppressing nucleation of the selector material over the layer 31 of nucleation inhibitor molecules. In some embodiments, top surfaces of the selector elements 130 may be formed within a horizontal plane including the top surface of the dielectric matrix layer 70. In one embodiment, the selector elements 130 comprise an ovonic threshold switch material (e.g., a chalcogenide semiconductor material), such as an ovonic threshold switch pillar. The sidewalls of at least the bottom portion of each selector element 130 that is located within a respective via cavity 891 is a free from any physical or chemical damage induced by etch process. In one embodiment, two or more precursors may be used alternatively during the selective ALD process. In this case, selector elements 130 comprise alternating layers of different materials. This process may be used to form a selector element film comprising three or more elements for desired ovonic threshold switch properties. By controlling the ratio of different ALD deposited layers (e.g. depositing n layers of GeSe and m layer of As₂Te₃) in one ALD supercycle, ternary or quaternary OTS selector element (e.g., a GeAsSeTe film) with desired stoichiometry may be provided.

In one embodiment, each of the selector elements 130 has a vertical sidewall having a bottom periphery that coincides with a top periphery of a tapered sidewall of an underlying lower electrode 880 of the two-dimensional array of lower electrodes 880. Thus, each selector element 130 may comprise the bottom periphery that coincides with the top periphery of an underlying lower electrode 880. Therefore, the selector elements 130 of the present disclosure are self aligned to the lower electrodes 880. The thickness of the selector elements 130 may be in a range from 5 nm to 100 nm, such as from 15 nm to 50 nm, although lesser and greater thicknesses may also be employed.

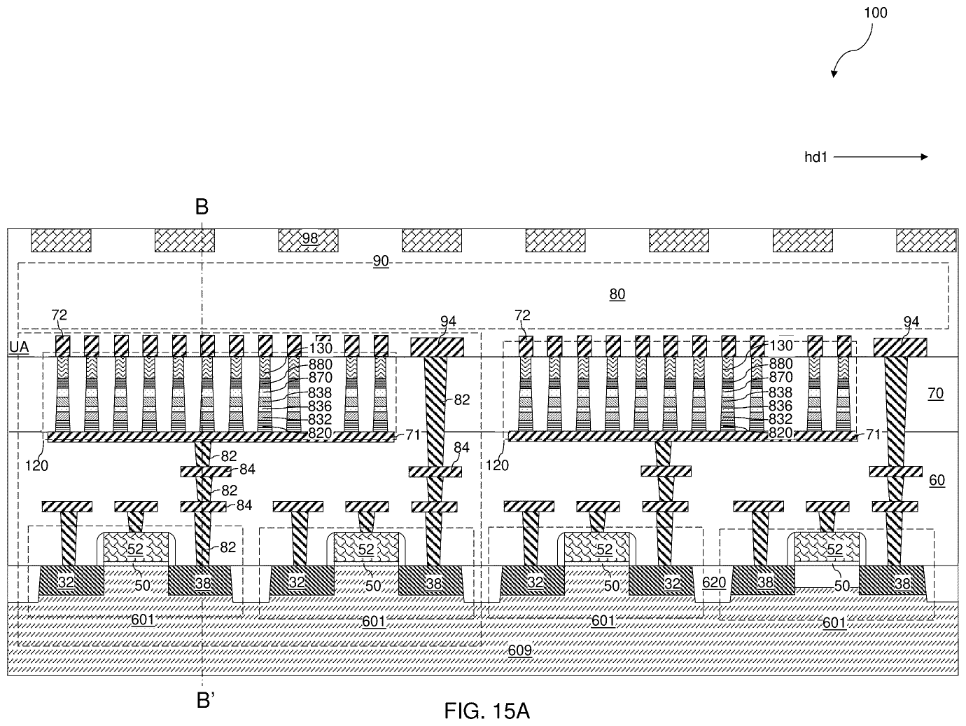

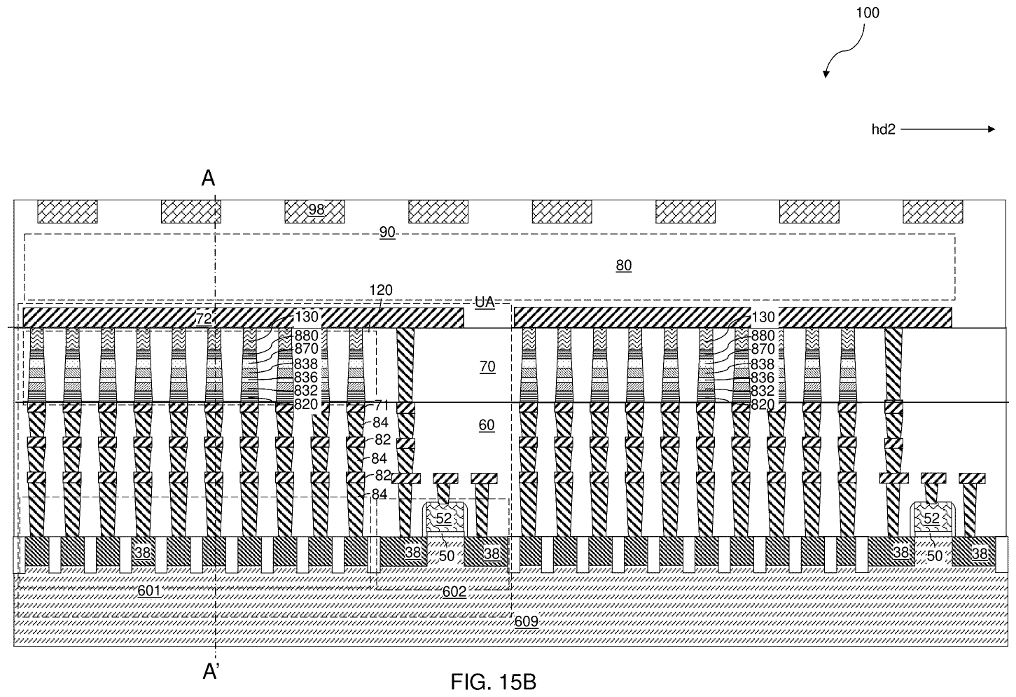

Referring to FIGS. 15A and 15B, second conductive lines 72 arranged along the second horizontal direction hd2 are formed in contact with a respective column of selector elements 130. The second conductive lines 72 function as upper electrodes for the selector elements 130. The second conductive lines 72 may comprise a metal, metal nitride or carbon nitride material. Optionally, additional metal via structures 82 may be formed through the dielectric matrix layer 70 and into the lower-level dielectric material layers 60 on top surfaces of a subset of the conductive lines 84 embedded within the lower-level dielectric material layers 60. Upper-level dielectric material layers 80 embedding upper-level metal interconnect structures 90 can be formed over a two-dimensional array of MRAM cells and the dielectric matrix layer 70. The upper-level dielectric material layers 80 may comprise a bottommost dielectric material layer, which is herein referred to as a second dielectric material layer.

If the second conductive lines 72 are formed by a damascene process, then line cavities extending along the second horizontal direction hd2 can be formed through the second dielectric material layer, and can be filled with at least one conductive material. Excess portions of the at least one conductive material can be removed from above the horizontal plane including the top surface of the second dielectric material layer. Remaining portions of the at least one conductive material filling the line cavities in the second dielectric material layer comprise the second conductive lines 72 contacting a respective column of selector elements 130 arranged along the second horizontal direction hd2. Alternatively, the second conductive lines 72 may be formed by deposition of a conductive layer over the array of the selector elements (e.g., selector pillars) 130 and then patterned into conductive lines which contact a respective column of the selector elements 130.

Generally, a one-dimensional array of second conductive lines 72 laterally extending along the second horizontal direction hd2 on the selector elements 130. The second conductive lines 72 may function as a second access lines for the two-dimensional array of MRAM cells. If the first conductive lines 71 function as word lines, the second conductive lines function as a bit lines, and vice versa.

Additional conductive lines 94, which are a subset of the upper-level metal interconnect structures 90, can be formed within the second dielectric material layer directly on a top surface of a respective one of the metal via structures 82 embedded within the dielectric matrix layer 70. The upper-level dielectric material layers 80 may comprise additional dielectric material layers, which may include via-level dielectric material layers line-level dielectric material layers. The upper-level metal interconnect structures 90 may comprise additional metal via structures (not shown) and a additional conductive line structures (not shown). Metallic contact pads 98 may be formed at the topmost level of the upper-level dielectric material layers 80.

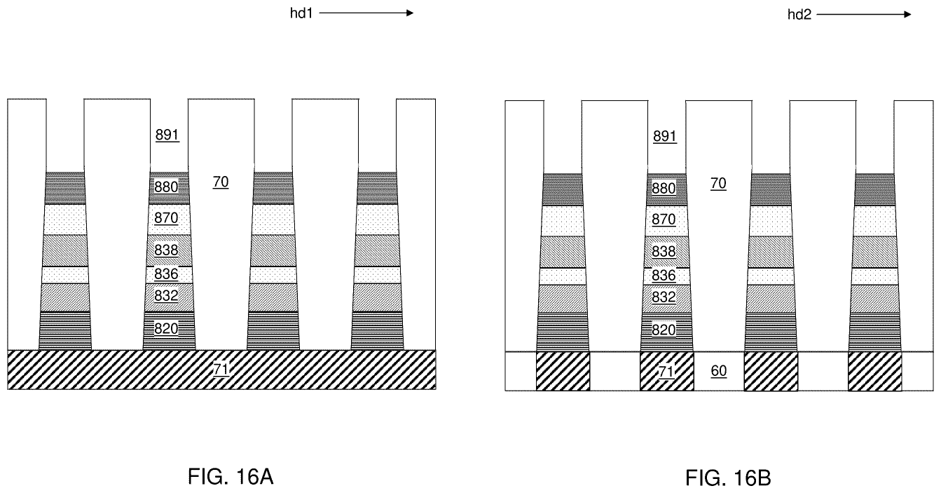

Referring to FIGS. 16A and 16B, a region of the exemplary structure in a second configuration according to the second embodiment is illustrated after removal of the two-dimensional array of sacrificial pillar structures 890 and formation of a two-dimensional array of via cavities 891. The second configuration of the exemplary structure at this processing step may be the same as the first configuration of the exemplary structure of the first embodiment described with reference to FIGS. 7A and 7B. The two-dimensional array of via cavities 891 can be formed by removing the two-dimensional array of sacrificial pillar structures 890 selective to the dielectric matrix layer 70 and selective to the array of magnetic tunnel junction stacks (820, 832, 836, 838, 870).

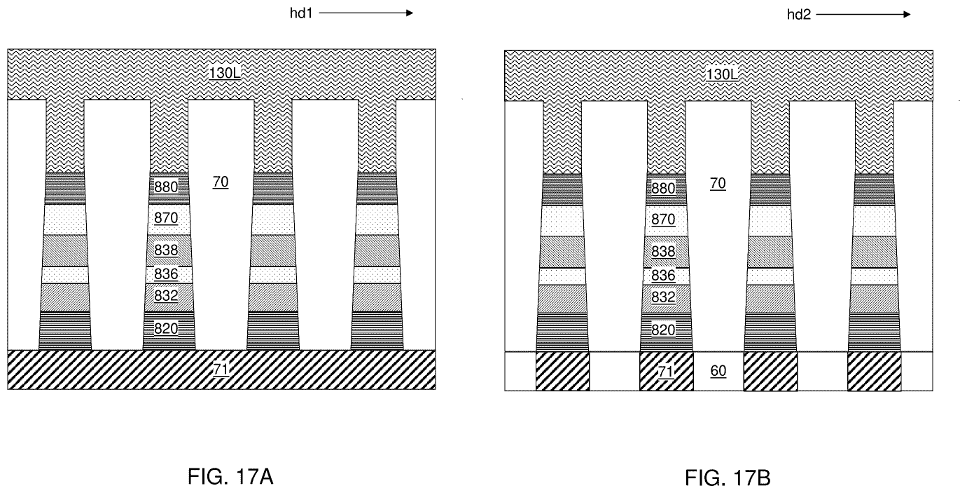

Referring to FIGS. 17A and 17B, a selector material, which may be an ovonic threshold switch (OTS) material, may be deposited in the two-dimensional array of via cavities 891 and over the dielectric matrix layer 70 to form a selector material layer 130L. The selector material layer 130L can be formed by performing the processing steps described with reference to FIGS. 8A-13B with a larger number of iterations of the set of unit processing steps described with reference to FIGS. 11A-13B, and/or by performing a physical vapor deposition which can deposit the selector material at a higher deposition rate. In one embodiment, the selector material layer 130L may be formed entirely by performing a physical vapor deposition process. In one embodiment, the selector material layer 130L entirely comprises an ovonic threshold switch material that is deposited by physical vapor deposition. The thickness of the horizontally extending portion of the selector material layer 130L that overlies the horizontal plane including the top surface of the dielectric matrix layer 70 may be in a range from 2 nm to 50 nm, although lesser and greater thicknesses may also be employed.

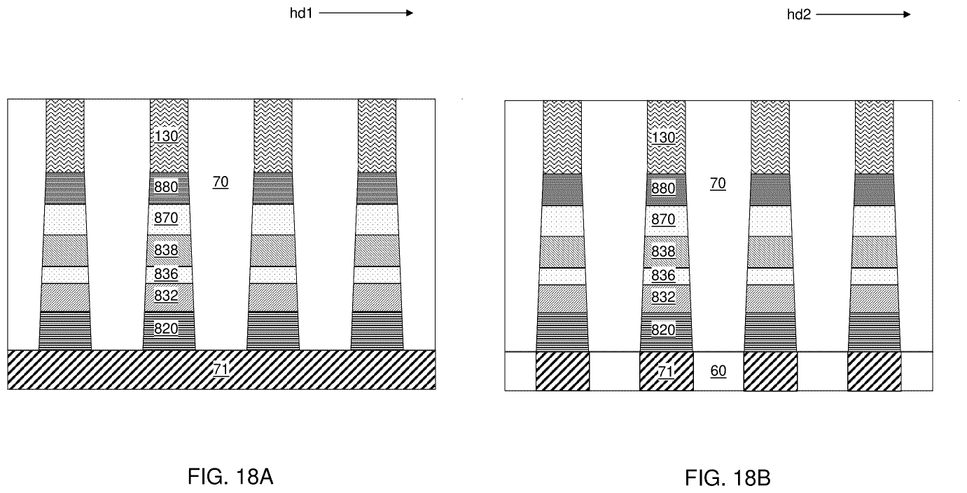

Referring to FIGS. 18A and 18B, a planarization process can be performed to remove portions of the selector material layer 130L from above the horizontal plane including the top surface of the dielectric matrix layer 70. The planarization process may comprise a chemical mechanical polishing process and/or a recess etch process. Each remaining portion of the selector material layer 130L that fills a respective one of the via cavities 891 constitutes a selector element 130. Each selector element 130 may have a shape of a cylindrical pillar. The bottom surface of each selector element 130 may have the same shape and the same area as the top surface of an underlying lower electrode 880. Thus, the selector elements 130 are self aligned to the lower electrodes 880.

In the second configuration of the exemplary structure illustrated in FIGS. 18A and 18B, the selector elements 130 are formed within the volumes of the two-dimensional array of via cavities 891. The selector elements 130 may comprise portions of an ovonic threshold switch material that is deposited by physical vapor deposition. In one embodiment, each of the selector elements 130 has a vertical sidewall having a bottom periphery that coincides with a top periphery of a tapered sidewall of an underlying lower electrode 880 among the two-dimensional array of lower electrodes 880.

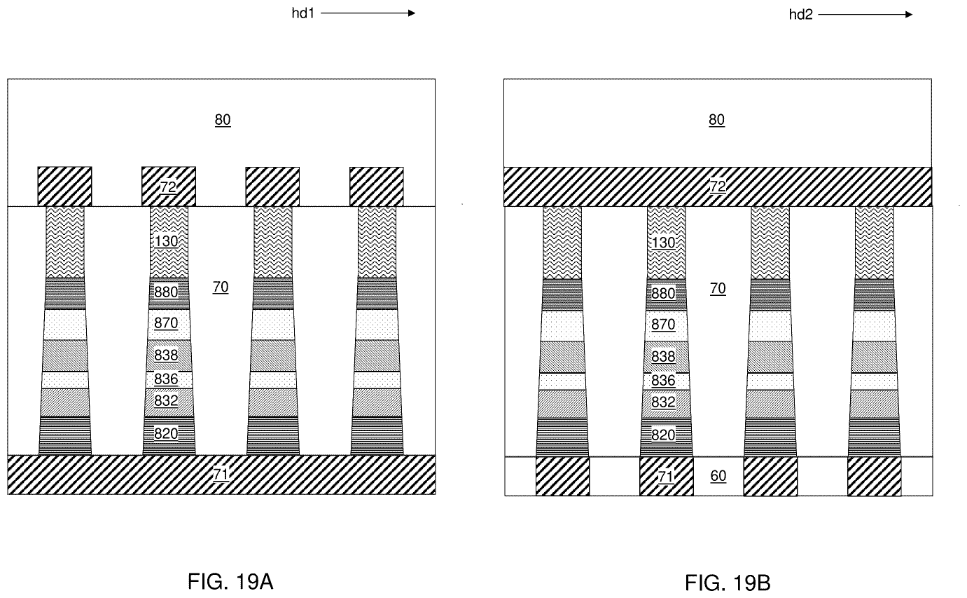

Referring to FIGS. 19A and 19B, the processing steps described with reference to FIGS. 15A and 15B may be subsequently performed to form second conductive lines 72 and upper-level dielectric material layers 80. The second conductive lines 72 may comprise a one-dimensional array of second conductive lines 72 laterally extending along a second horizontal direction hd2 and contacting a top surfaces of a two-dimensional array of selector elements 130.

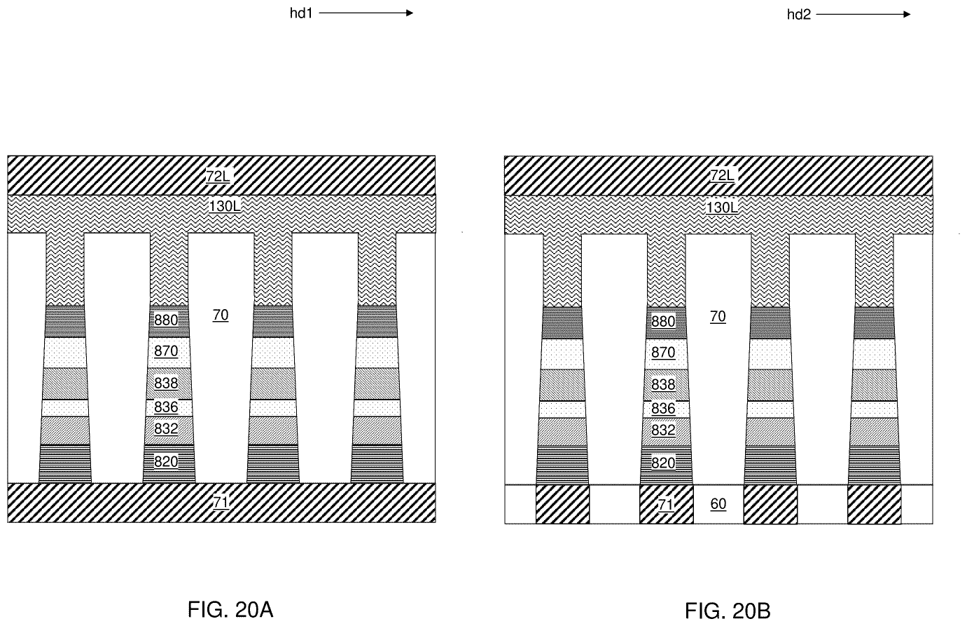

Referring to FIGS. 20A and 20B, a third configuration of the exemplary structure according to the third embodiment may be derived from the second configuration of the exemplary structure described with reference to FIGS. 17A and 17B by forming a second metallic material layer 72L on the selector material layer 130L without performing the planarization process described with reference to FIGS. 18A and 18B. The second metallic material layer 72L may comprise any material that may be employed for the second conductive lines 72 described above.

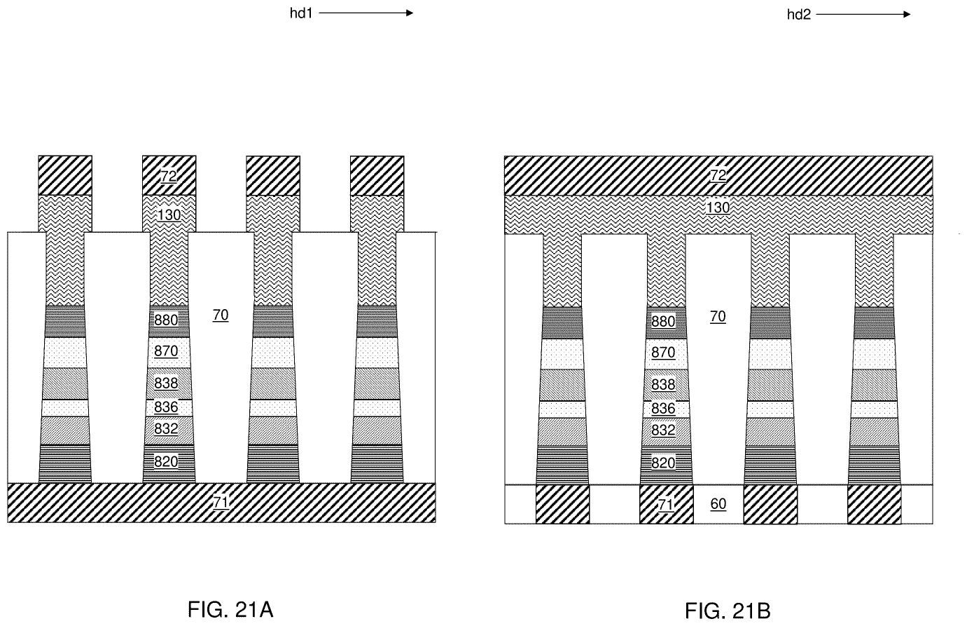

Referring to FIGS. 21A and 21B, a photoresist layer (not shown) may be applied over the second metallic material layer 72L, and can be lithographically patterned in a line-and-space pattern having a periodicity along the first horizontal direction hd1 and laterally extending along the second horizontal direction hd2. The line portions of the line-and-space pattern has an aerial overlap in a plan view (such as a top-down view) with a respective column of magnetic tunnel junction stacks (820, 832, 836, 838, 870) and the respective column of lower electrodes 880. The space portions of the line-and-space pattern has an aerial overlap in the plan view with the dielectric matrix layer 70. An anisotropic etch process can be performed to transfer the line-and-space pattern in the photoresist layer through the second metallic material layer 72L and through the horizontally extending portion of the selector material layer 130L. The second metallic material layer 72L is divided into second conductive lines 72, which can be a one-dimensional periodic array of second conductive lines 72. The selector material layer 130L is divided into a one-dimensional periodic array of the selector elements 130. Each selector element 130 comprises of horizontally extending portion (e.g., a horizontally extending rail) overlying the horizontal plane including the top surface of the dielectric matrix layer 70, and further comprises a column of downward protruding pillar portions filling a respective one of the via cavities 891. In other words, each selector element 130 may have a comb shape including a horizontally-extending portion that extends along the second horizontal direction hd2, and a one-dimensional array of pillar portions adjoined to a bottom surface of the horizontally-extending portion and overlying a respective one of the lower electrodes 880.

In summary, the selector elements 130 can be formed at least within volumes of the two-dimensional array of via cavities 891. The one-dimensional array of second conductive lines 72 laterally extending along the second horizontal direction hd2 is formed on the selector elements 130, which is arranged as a one-dimensional periodic array of the selector elements 130. The one-dimensional array of selector elements 130 overlies the two-dimensional array of lower electrodes 880. The dielectric matrix layer 70 laterally surrounds the two-dimensional array of sacrificial pillar structures 890 and the two-dimensional array of lower electrodes 880. In one embodiment, each of the selector elements 130 has a vertical sidewall having a bottom periphery that coincides with a top periphery of a tapered sidewall of an underlying lower electrode 880 among the two-dimensional array of lower electrodes 880.

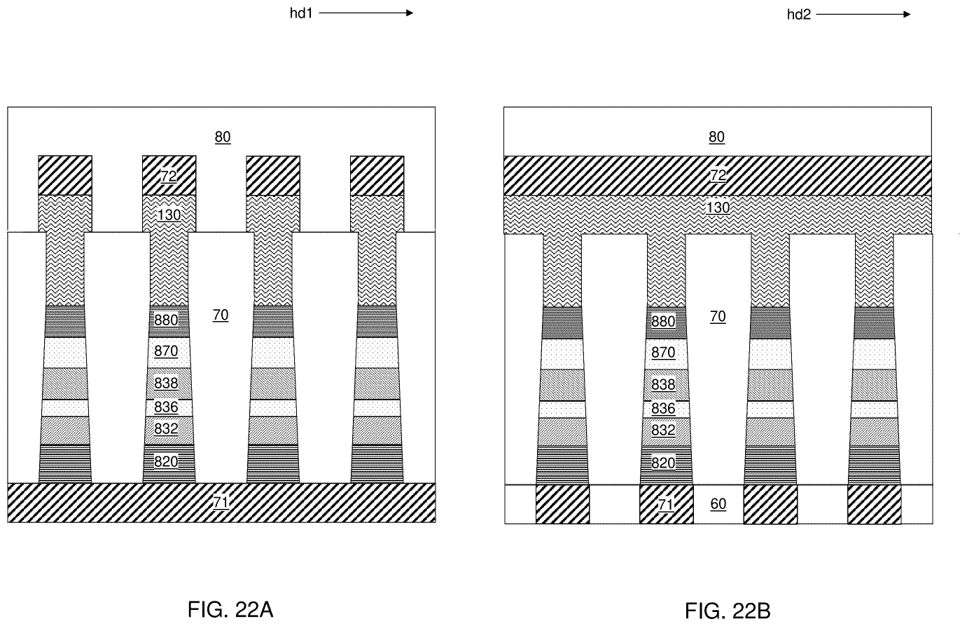

Referring to FIGS. 22A and 22B, upper-level dielectric material layers 80 and additional upper-level metal interconnect structures 90 (not shown in FIGS. 22A and 22B) can be formed over the second conductive lines 72 by performing the processing steps described with reference to FIGS. 15A and 15B.

Referring collectively to FIGS. 22A, 22B, 15A, 15B, and other related drawings and according to various embodiments of the present disclosure, a magnetoresistive memory array comprises: a one-dimensional array of first conductive lines 71 laterally extending along a first horizontal direction hd1 and overlying a substrate (such as a semiconductor substrate 609); an array of magnetic tunnel junction stacks (820, 832, 836, 838, 870) each comprising a reference layer 832, a tunnel barrier layer 836, at least one free layer 838 overlying the one-dimensional array of first conductive lines 71; a two-dimensional array of lower electrodes 880 overlying the array of magnetic tunnel junction stacks (820, 832, 836, 838, 870); an array of selector elements 130 overlying the two-dimensional array of lower electrodes 880, wherein each of the selector elements 130 has a vertical sidewall having a bottom periphery that coincides with a top periphery of a tapered sidewall of an underlying lower electrode 880 of the two-dimensional array of lower electrodes 880; a dielectric matrix layer 70 laterally surrounding the two-dimensional array of the selector elements 130 and the two-dimensional array of lower electrodes 880; and a one-dimensional array of second conductive lines 72 laterally extending along a second horizontal direction hd2 and contacting at least one selector element 130 within the array of selector elements 130. In one embodiment, each selector element 130 within the array of selector elements 130 comprises: a horizontally-extending portion that extends along the second horizontal direction hd2; and a one-dimensional array of pillar portions adjoined to a bottom surface of the horizontally-extending portion and overlying a respective one of the lower electrodes 880.

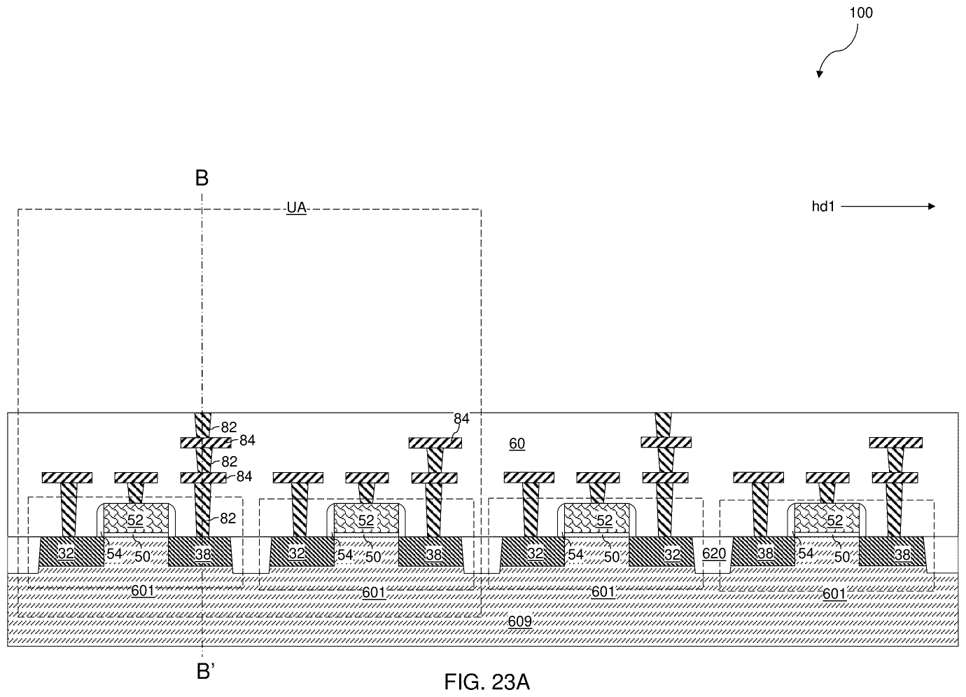

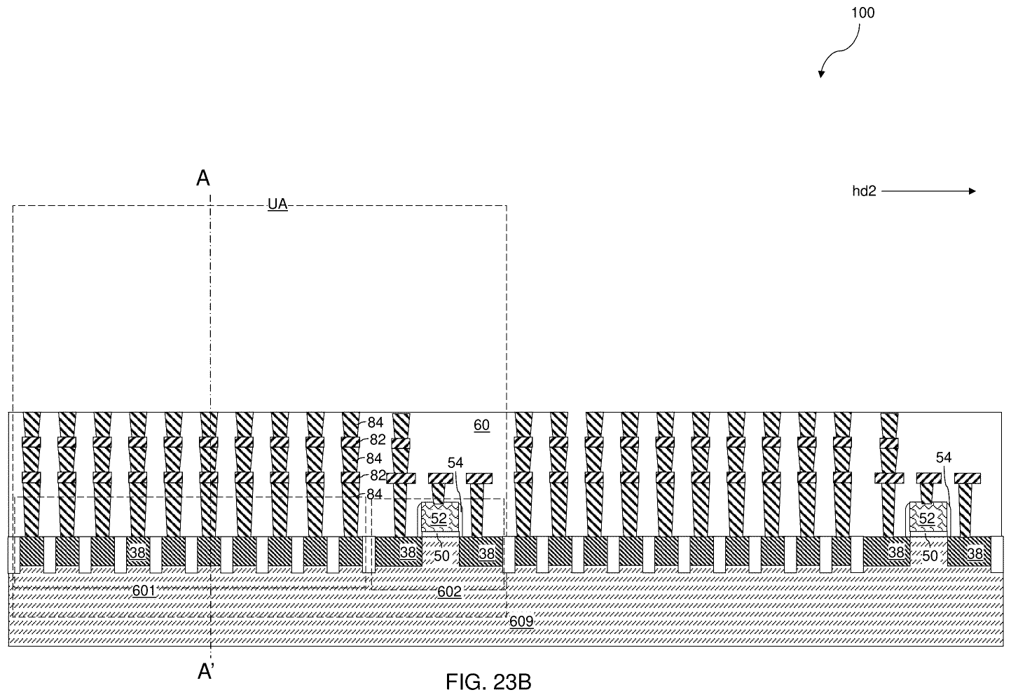

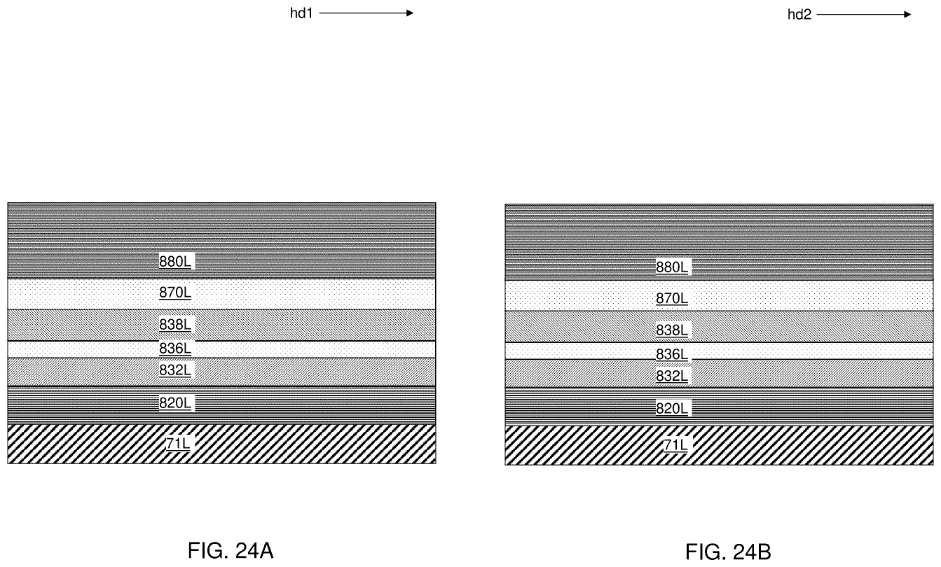

Referring to FIGS. 23A and 23B, a fourth configuration of the exemplary structure according to the fourth embodiment is illustrated after formation of driver circuits (601, 602) and lower-level metal interconnect structures (82, 84) embedded in lower-level dielectric material layers 60. The fourth configuration of the exemplary structure illustrated in FIGS. 23A and 23B can be derived from the first configuration of the exemplary structure illustrated in FIGS. 1A and 1B by omitting the processing steps for forming the first conductive lines 71. For example, the first metallic material layer 71L may comprise a combination of the metallic barrier liner (not expressly shown) and a metal layer (not expressly shown). The metallic barrier liner may comprise a metal nitride material, such as TiN, TaN, WN, MON, or a combination thereof, and may have a thickness in a range from 3 nm to 30 nm, although lesser and greater thicknesses may also be employed. The metal layer comprises a metal having high electrical conductivity such as Cu, W, Ti, Ta, Mo, Co, Ru, etc. The thickness of the metal layer may be in a range from 30 nm to 300 nm, although lesser and greater thicknesses may also be employed.

The layer stack (820L, 832L, 836L, 838L, 870L) including a continuous magnetic polarizer layer 820L, a continuous reference layer 832L, a continuous tunnel barrier layer 836L, a continuous free layer 838L, and a continuous dielectric capping layer 870L can be deposited over the first metallic material layer 71L. The layer stack (820L, 832L, 836L, 838L, 870L) in the fourth configuration of the exemplary structure may be the same as the layer stack (820L, 832L, 836L, 838L, 870L) described with reference to FIGS. 2A and 2B.

The lower electrode layer 880L can be subsequently deposited over the layer stack (820L, 832L, 836L, 838L, 870L). The lower electrode layer 880L in the fourth exemplary structure is a subsequently employed as a hard mask layer. As such, the thickness of the lower electrode layer 880L in the fourth exemplary structure may be greater than the thickness of the lower electrode layer 880L employed in the first exemplary structure. The thickness of the lower electrode layer 880L in the fourth exemplary structure may range from 40 nm to 300 nm, such as from 80 nm to 150 nm, although lesser and greater thicknesses may also be employed. The lower electrode layer 880L may be formed by physical vapor deposition (PVD).

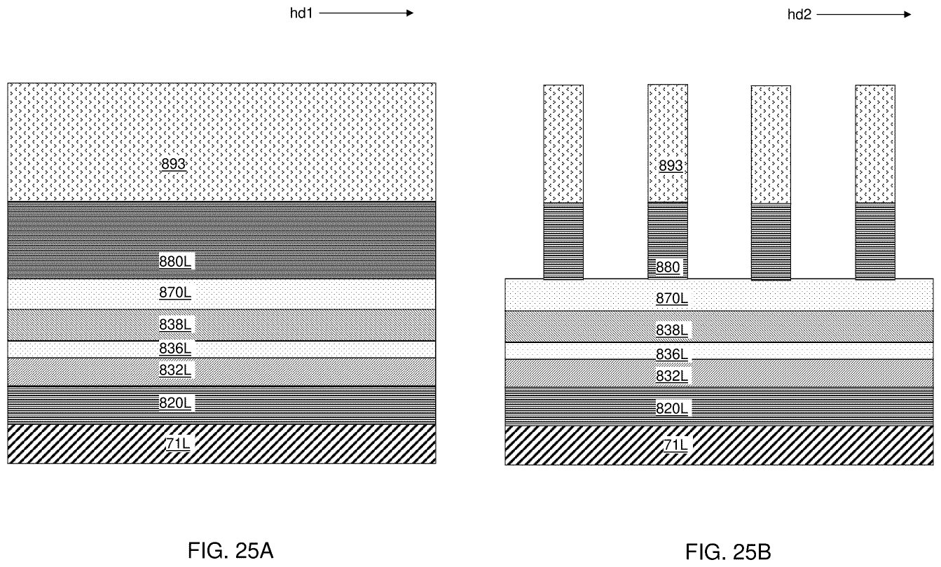

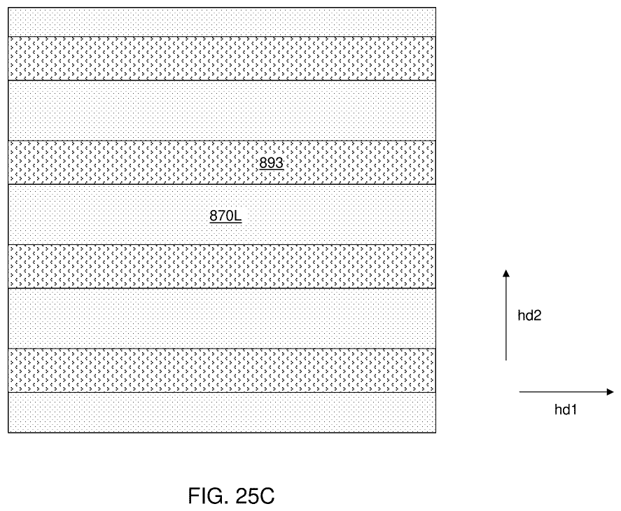

Referring to FIGS. 25A-25C, a one-dimensional array of etch mask portions (such as a patterned photoresist layer 893) is formed over the lower electrode layer 880L. The one-dimensional array of etch mask portions may comprise a line-and-space pattern that is repeated along the second horizontal direction hd2, and laterally extends along the first horizontal direction hd1. The width of the line patterns along the second horizontal direction hd2 can be the same as the width of magnetic tunnel junction stacks to be subsequently formed along the second horizontal direction hd2. The pitch of the line-and-space pattern along the second horizontal direction hd2 can be the same as the pitch of the magnetic tunnel junction stacks to be subsequently formed along the second horizontal direction hd2. An anisotropic etch process can be performed to transfer the pattern in the one-dimensional array of etch mask portions (such as the patterned photoresist layer 893) through the lower electrode layer 880L. The lower electrode layer 880L is patterned into lower electrodes 880, which may be arranged as a one-dimensional periodic array of lower electrodes 880. The one-dimensional array of etch mask portions (such as the patterned photoresist layer 893) may be subsequently removed, for example, by ashing.

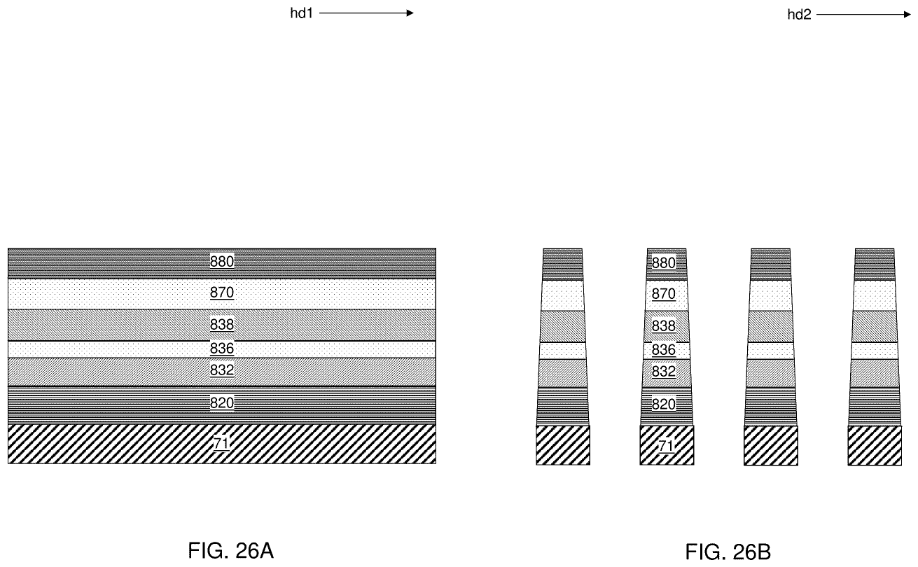

Referring to FIGS. 26A and 26B, an etch process can be performed to transfer the pattern in the lower electrodes 880 through the layer stack (820L, 832L, 836L, 838L, 870L) and the first metallic material layer 71L. An ion beam etch process described with reference to FIGS. 4A and 4B may be performed with modifications in the process parameter in view of the use of the lower electrodes 880 as an etch mask structure and in view of the need to etch through unmasked portions of the first metallic material layer 71L.

The lower electrodes 880 can be collaterally etched during the ion beam etch process, and particularly during patterning of the first metallic material layer 71L. Thus, during the ion beam etch process. The final thickness of the lower electrodes 880 after the ion beam etch process may be about the same as the thickness of the lower electrodes 880 employed in the first, second, and the third embodiments. For example, the thickness of the lower electrodes 880 after the ion beam etch process may be in a range from 5 nm to 50 nm, although lesser and greater thicknesses may also be employed.

The layer stack (820L, 832L, 836L, 838L, 870L) can be patterned into a one-dimensional array of magnetic tunnel junction stacks (820, 832, 836, 838, 870) (e.g., MTJ rails). The first metallic material layer 71L can be patterned into the first conductive lines 71. Each of the magnetic tunnel junction stacks (820, 832, 836, 838, 870) and the first conductive lines 71 may be formed as a respective rail structure. As used herein, a rail structure refers to a structure that extends along a horizontal direction with a uniform vertical cross-sectional shape along vertical planes that are perpendicular to the lengthwise direction.

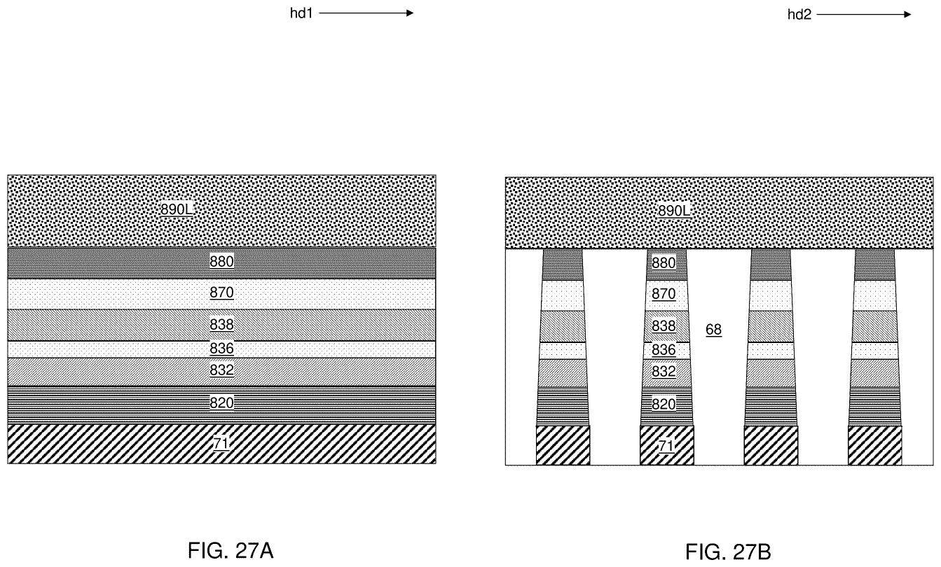

Referring to FIGS. 27A and 27B, a dielectric fill material, such as silicon oxide, can be deposited in the gaps between neighboring pairs of the first conductive lines 71 and between neighboring pairs of magnetic tunnel junction stacks (820, 832, 836, 838, 870), and over the magnetic tunnel junction stacks (820, 832, 836, 838, 870). A planarization process, such as a chemical mechanical polishing process, can be performed to remove portions of the dielectric fill material from above the horizontal plane including the top surfaces of the lower electrodes 880. Remaining portions of the dielectric fill material located between neighboring pairs of magnetic tunnel junction stacks (820, 832, 836, 838, 870) comprise dielectric material rails. These rails are herein referred to as insulating rails 68. The insulating rails 68 laterally extend along the first horizontal direction hd1, and are arranged as a one-dimensional periodic array of insulating rails 68 having a periodicity along the second horizontal direction hd2.

Subsequently, a sacrificial pillar material layer 890L can be formed over the one-dimensional array of magnetic tunnel junction stacks (820, 832, 836, 838, 870) and over the one-dimensional periodic array of insulating rails 68. The sacrificial pillar material layer 890L in the fourth configuration of the exemplary structure may have the same material composition as the sacrificial pillar material layer 890L in the first configuration of the exemplary structure described with reference to FIGS. 2A and 2B. The thickness of the sacrificial pillar material layer 890L in the fourth configuration of the exemplary structure may be less than the thickness of the sacrificial pillar material layer 890L employed in the first configuration of the exemplary structure. The thickness of the sacrificial pillar material layer 890L in the fourth configuration of the exemplary structure may be in a range from 30 nm to 200 nm, such as from 60 nm to 100 nm, although lesser and greater thicknesses may also be employed. The sacrificial pillar material layer 890L may comprise and/or may consist essentially of diamond-like carbon.

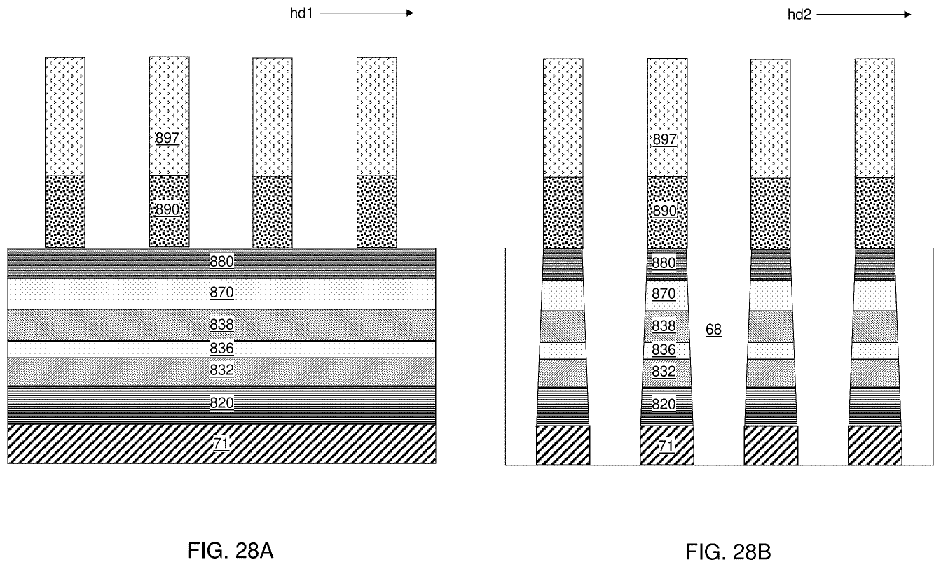

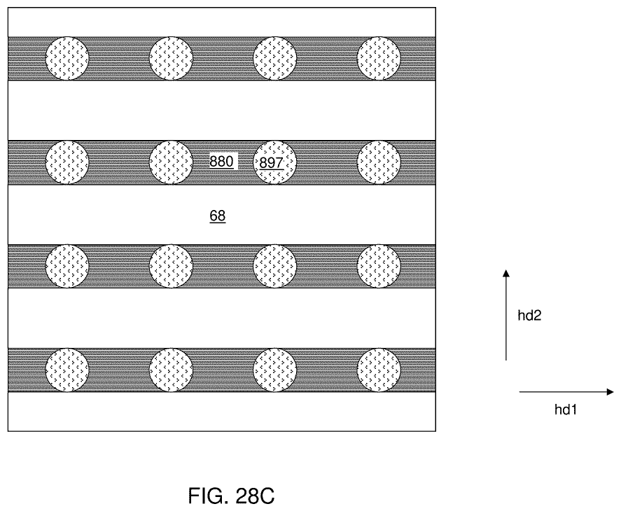

Referring to FIGS. 28A-28C, a two-dimensional array of etch mask portions can be formed over the sacrificial pillar material layer 890L. In one embodiment, the two-dimensional array of etch mask portions may comprise a patterned photoresist layer 897, which can be formed by applying a blanket photoresist material layer over the sacrificial pillar material layer 890L and by lithographically patterning the blanket photoresist material layer, i.e., by performing a lithographic exposure process and a lithographic development process. The patterned photoresist layer 897 may comprise a two-dimensional periodic array of discrete patterned photoresist material portions having cylindrical shapes. In one embodiment, the two-dimensional periodic array may comprise a two-dimensional rectangular array. Each of the discrete patterned photoresist material portions may have a respective circular horizontal cross-sectional shape having a diameter in a range from 20 nm to 100 nm, although lesser and greater dimensions may also be employed. Alternatively, the discrete patterned photoresist material portions may have non-circular cross-sectional shapes, such as oval or rectangular shapes. Each row of discrete patterned photoresist material portions arranged along the first horizontal direction hd1 may be formed within the area of a respective one of the magnetic tunnel junction stacks (820, 832, 836, 838, 870).

An anisotropic etch process, such as a reactive ion etch process and/or an ion beam etch process, can be performed to pattern the sacrificial pillar material layer 890L into a two-dimensional array of sacrificial pillar structures 890 employing the two-dimensional array of etch mask portions (such as the patterned photoresist layer 897) as an etch mask. If the sacrificial pillar material layer 890L comprises diamond-like carbon, the reactive ion etch process may employ an oxygen-based etch chemistry. The anisotropic etch process transfers the pattern in the two-dimensional array of etch mask portions (such as the patterned photoresist layer 897) through the sacrificial pillar material layer 890L. Remaining patterned portions of the sacrificial pillar material layer 890L comprise a two-dimensional array of sacrificial pillar structures 890, each of which may have a respective cylindrical shape. The two-dimensional array of etch mask portions (which may comprise a patterned photoresist layer 897) can be subsequently removed, for example, by ashing.

In summary, the two-dimensional array of sacrificial pillar structures 890 may be formed over the insulating rails 68 and the array of magnetic tunnel junction stacks (820, 832, 836, 838, 870) by depositing and patterning a sacrificial pillar material layer 890L to form a stack structure. The stack structure includes a one-dimensional array of first conductive lines 71 laterally extending along a first horizontal direction hd1, an array of magnetic tunnel junction stacks (e.g., rails) (820, 832, 836, 838, 870) each comprising a magnetic polarizer layer 820, a reference layer 832, a tunnel barrier layer 836, a free layer 838, and an optional dielectric capping layer 870, located below a two-dimensional array of sacrificial pillar structures 890. In one embodiment, the two-dimensional array of sacrificial pillar structures 890 comprises diamond-like carbon.

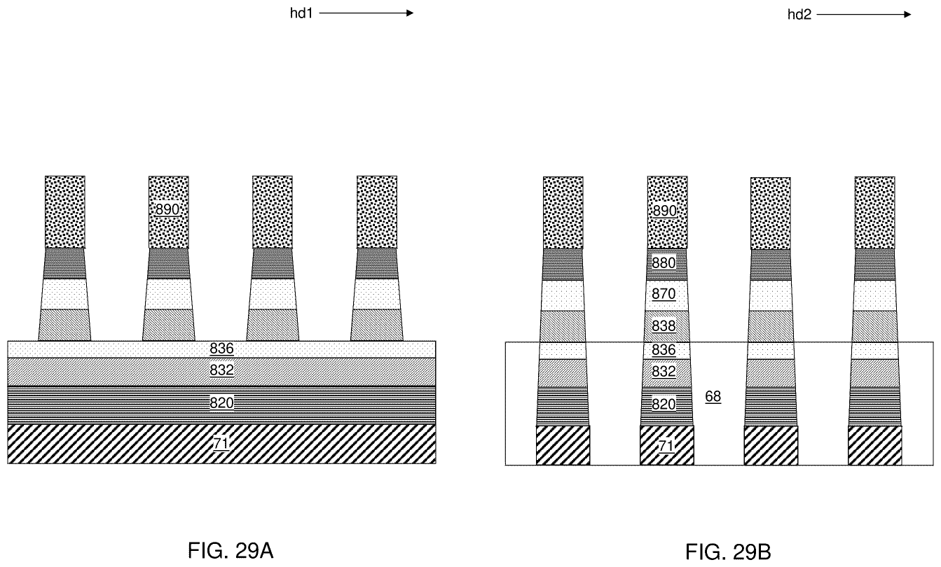

Referring to FIGS. 29A and 29B, the insulating rails 68 and unmasked portions of the lower electrodes 880, the dielectric capping layers 870, and the free layers 838 can be vertically etched employing the two-dimensional array of sacrificial pillar structures 890 as an etch mask. In one embodiment, an ion beam etch process described with reference to FIGS. 4A and 4B may be employed with suitable modifications in the process parameters in view of the change in the target etch materials to a combination of the materials of the lower electrodes 880, the dielectric capping layers 870, the free layers 838, and the insulating rails 68, and in view of the modification of the etch depth so that the reference layers 832 are not etched. The tunnel barrier layers 836 may be partially etched, not etched at all, or may be completely etched.

Generally, portions of the insulating rails 68 and the array of magnetic tunnel junction stacks (e.g., rails) (820, 832, 836, 838, 870) that are not masked by the two-dimensional array of sacrificial pillar structures 890 are vertically etched. Top surfaces of the insulating rails 68 are vertically recessed at least to a horizontal plane including bottom surfaces of the free layers 838 within the array of magnetic tunnel junction stacks (820, 832, 836, 838, 870). Remaining portions of the free layers 838 comprise a two-dimensional array of free layers (e.g., free layer plates) 838. The reference layers 832 remain as a one-dimensional array of reference layers (i.e., an array of reference layer rails) 832. The thickness of the sacrificial pillar structures 890 after the etch process may be in a range from 5 nm to 100 nm, such as from 15 nm to 50 nm, although lesser and greater thicknesses may also be employed.

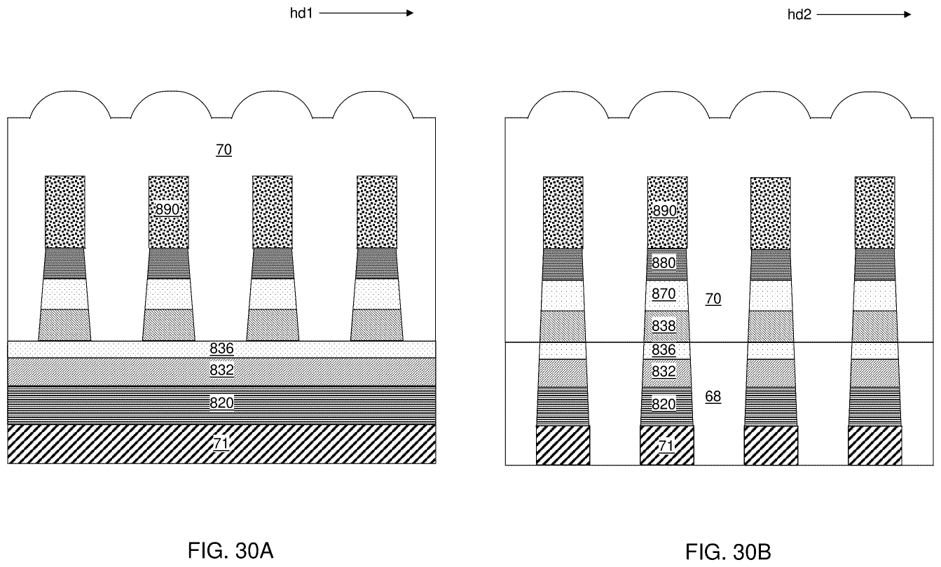

Referring to FIGS. 30A and 30B, the processing steps described with reference to FIGS. 5A and 5B can be performed to form the dielectric matrix layer 70. The dielectric matrix layer 70 laterally surrounds the two-dimensional array of sacrificial pillar structures 890. A bottom surface of the dielectric matrix layer 70 is formed on the recessed top surfaces of the insulating rails 68 and on horizontal surfaces of the tunnel barrier layers 836 within the array of magnetic tunnel junction stacks (820, 832, 836, 838, 870).

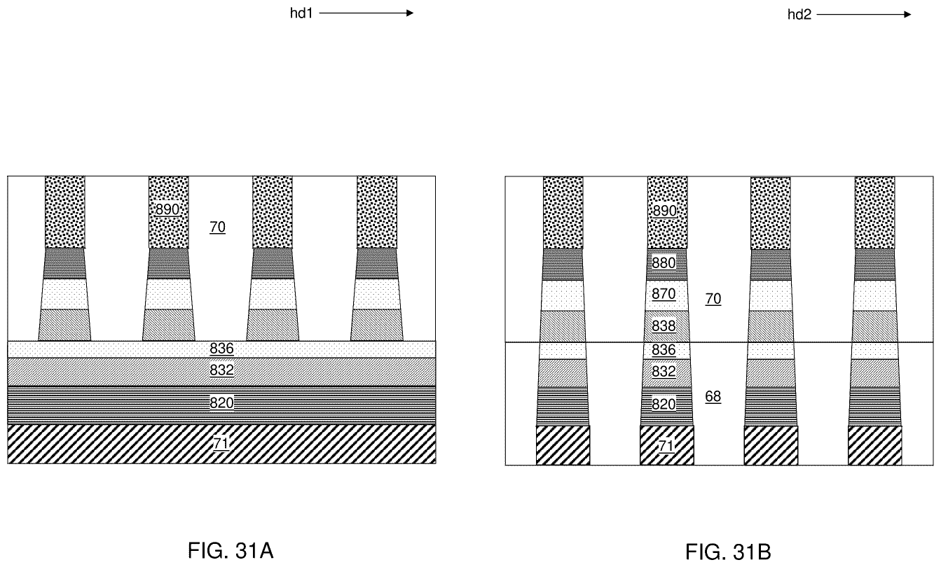

Referring to FIGS. 31A and 31B, the processing steps described with reference to FIGS. 6A and 6B can be performed to planarize the dielectric matrix layer 70. Generally, the dielectric matrix layer 70 may be formed by depositing a dielectric fill material around and over the two-dimensional array of sacrificial pillar structures 890, and by performing a planarization process that removes portions of the deposited dielectric fill material from above a horizontal plane including top surfaces of the two-dimensional array of sacrificial pillar structures 890. The top surface of the dielectric matrix layer 70 is a planar surface after performing the planarization process. In one embodiment, the top surface of the dielectric matrix layer 70 may be located within the horizontal plane including the top surfaces of the sacrificial pillar structures 890 after the planarization process.

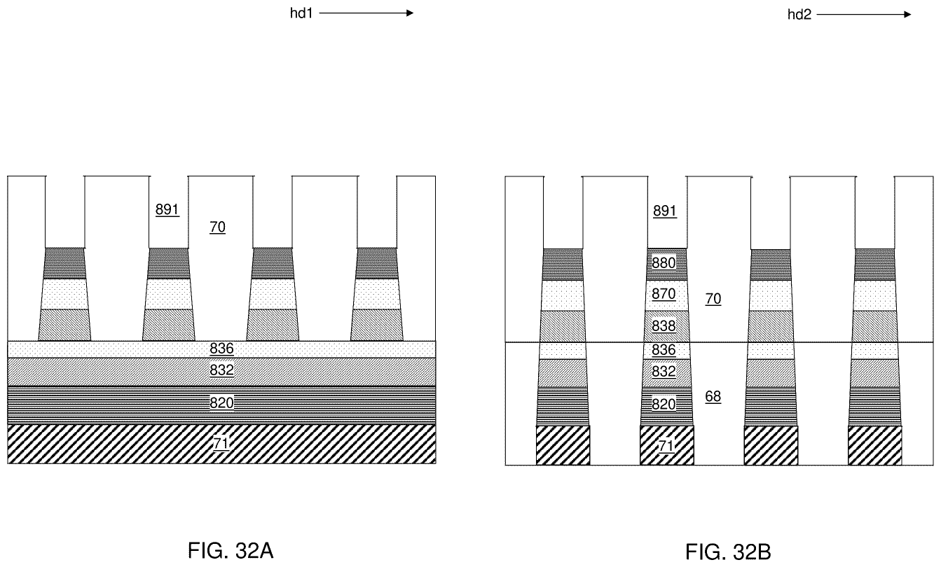

Referring to FIGS. 32A and 32B, the processing steps described with reference to FIGS. 7A and 7B can be performed. A two-dimensional array of via cavities 891 can be formed by removing the two-dimensional array of sacrificial pillar structures 890 selective to the dielectric matrix layer 70 and selective to the array of magnetic tunnel junction stacks (820, 832, 836, 838, 870).

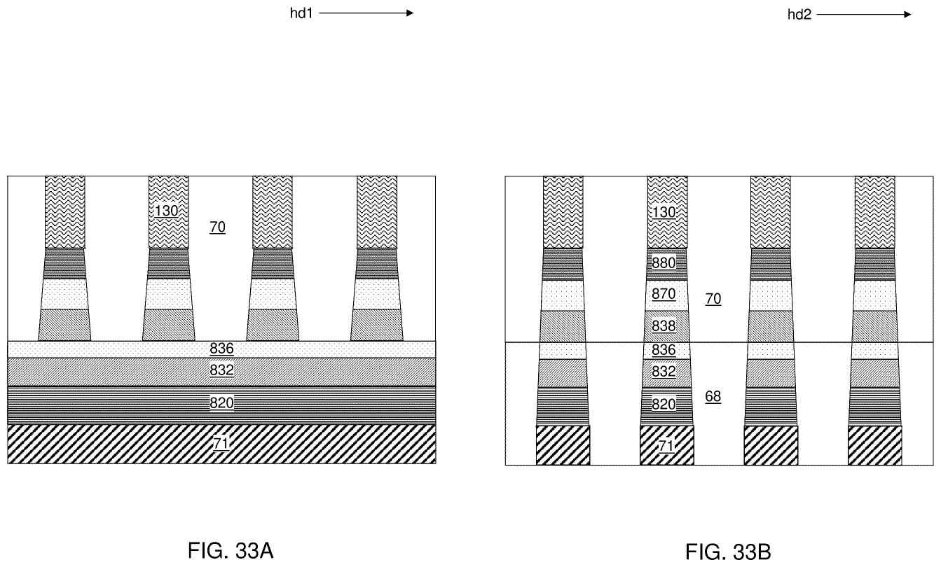

Referring to FIGS. 33A and 33B, any of the processing steps for forming selector elements 130 described above may be performed to form an array of selector elements. In the illustrated example, processing steps described with reference to the first or third embodiments may be employed. Alternatively the processing steps described with reference to the second embodiment may be employed. The thickness of each portion of the selector elements 130 located within a respective one of the via cavities 891 may be in a range from 5 nm to 100 nm, such as from 15 nm to 50 nm, although lesser and greater thicknesses may also be employed.

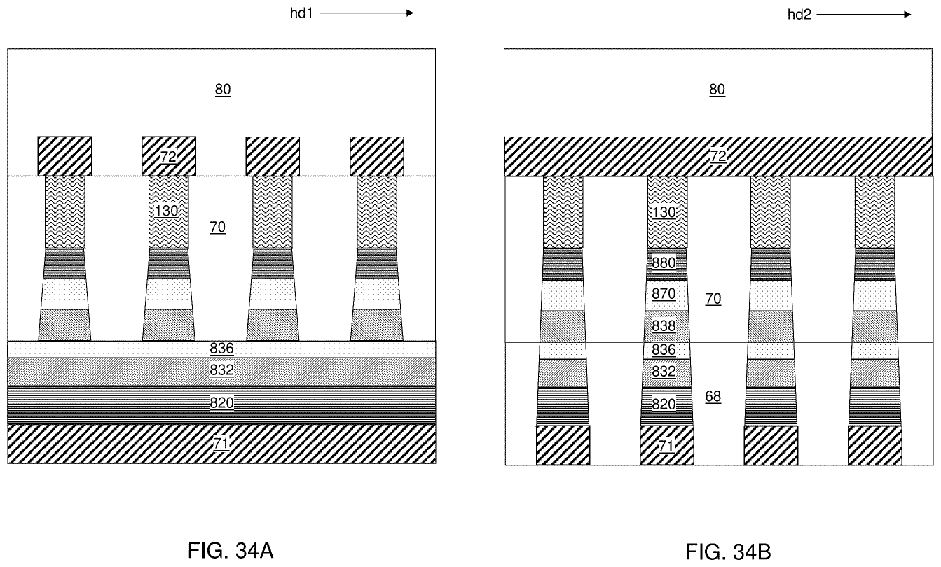

Referring to FIGS. 34A and 34B, any of the processing steps described above for forming second conductive lines 72 and upper-level dielectric material layers 80 may be performed. Thus, the selector elements 130 are formed at least within volumes of the two-dimensional array of via cavities 891. An array of selector elements 130 overlies the two-dimensional array of lower electrodes 880. Each of the selector elements 130 has a vertical sidewall having a bottom periphery that coincides with a top periphery of a tapered sidewall of an underlying lower electrode 880 of the two-dimensional array of lower electrodes 880. In one embodiment, each of the magnetic tunnel junction stacks (820, 832, 836, 838, 870) comprises one magnetic polarizer layer 820, one reference layer 832, and a plurality of free layers 838 that are arranged along the first horizontal direction hd1 and overlying said one reference layer 832. In other words, a row of free layers (e.g., free layer plates) 838 arranged along the first horizontal direction hd1 may overlie and may be magnetically coupled to a common reference layer (e.g., reference layer rail) 832 having a configuration of a rail structure and laterally extending along the first horizontal direction hd1.

In the fourth embodiment, each of the magnetic tunnel junction stacks comprises one reference layer 832, and a plurality of free layers 838 that are arranged along the first horizontal direction hd1 and overlying said one reference layer 832.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method of forming a magnetoresistive memory array, comprising:
forming a stack structure including a one-dimensional array of first conductive lines laterally extending along a first horizontal direction, an array of magnetic tunnel junction stacks each comprising a reference layer, a tunnel barrier layer, and a free layer located over the first conductive lines, and a two-dimensional array of sacrificial pillar structures located over the array of magnetic tunnel junction stacks;
forming a dielectric matrix layer laterally surrounding the two-dimensional array of sacrificial pillar structures;
forming a two-dimensional array of via cavities by removing the two-dimensional array of sacrificial pillar structures selective to the dielectric matrix layer;
forming selector elements at least within volumes of the two-dimensional array of via cavities; and
forming a one-dimensional array of second conductive lines laterally extending along a second horizontal direction over the selector elements.

2. The method of claim 1, wherein:
the dielectric matrix layer is formed by depositing a dielectric fill material around and over the two-dimensional array of sacrificial pillar structures, and by performing a planarization process that removes portions of the deposited dielectric fill material from above a horizontal plane including top surfaces of the two-dimensional array of sacrificial pillar structures; and
a top surface of the dielectric matrix layer comprises a planar surface after performing the planarization process.

3. The method of claim 1, wherein the two-dimensional array of sacrificial pillar structures comprises diamond-like carbon sacrificial pillar structures.

4. The method of claim 1, wherein:
the one-dimensional array of first conductive lines are located within a first dielectric material layer;
the array of magnetic tunnel junction stacks is formed by depositing and patterning a layer stack including a continuous reference layer, a continuous tunnel barrier layer, and a continuous free layer over the one-dimensional array of first conductive lines and over first dielectric material layer; and
the two-dimensional array of sacrificial pillar structures is formed over the layer stack by depositing and patterning a sacrificial pillar material layer.

5. The method of claim 4, further comprising:
forming a two-dimensional array of etch mask portions over the sacrificial pillar material layer; and
performing an anisotropic etch process that transfers a pattern in the two-dimensional array of etch mask portions through the sacrificial pillar material layer, wherein remaining patterned portions of the sacrificial pillar material layer comprise the two-dimensional array of sacrificial pillar structures.

6. The method of claim 4, wherein the layer stack is patterned by performing an etch process that etches unmasked portions of the layer stack employing the two-dimensional array of sacrificial pillar structures as an etch mask.

7. The method of claim 1, further comprising:
forming a first metallic material layer and a layer stack including a continuous reference layer, a continuous tunnel barrier layer, and a continuous free layer over the substrate;
forming a one-dimensional array of etch mask portions over the layer stack; and
transferring a pattern of the one-dimensional array of etch mask portions through the layer stack and the first metallic material layer, wherein patterned portions of the layer stack comprise the array of magnetic tunnel junction stacks, and patterned portions of the first metallic material layer comprises the one-dimensional array of first conductive lines.

8. The method of claim 7, further comprising:
forming an electrically conductive metal, metal nitride or carbon nitride lower electrode layer over the layer stack, wherein the one-dimensional array of etch mask portions is formed over the lower electrode layer, and the pattern of the one-dimensional array of etch mask portions is transferred through the lower electrode layer to pattern the lower electrode layer into lower electrodes; and
the pattern of the one-dimensional array of etch mask portions is transferred through the layer stack and the first metallic material layer by performing an etch process that employs the lower electrodes as an etch mask structure.

9. The method of claim 7, further comprising forming insulating rails between neighboring pairs of magnetic tunnel junction stacks within the array of magnetic tunnel junction stacks.

10. The method of claim 9, wherein the two-dimensional array of sacrificial pillar structures is formed over the insulating rails and the array of magnetic tunnel junction stacks by depositing and patterning a sacrificial pillar material layer.

11. The method of claim 10, further comprising vertically recessing portions of the insulating rails and etching the array of magnetic tunnel junction stacks that are not masked by the two-dimensional array of sacrificial pillar structures, wherein top surfaces of the insulating rails are vertically recessed at least to a horizontal plane including bottom surfaces of the free layers within the array of magnetic tunnel junction stacks, and wherein remaining portions of the free layers comprise a two-dimensional array of free layers.

12. The method of claim 11, wherein a bottom surface of the dielectric matrix layer is formed on the recessed top surfaces of the insulating rails and on horizontal surfaces of the tunnel barrier layers within the array of magnetic tunnel junction stacks.

13. The method of claim 1, further comprising:
forming an array of lower electrodes over the array of magnetic tunnel junction stacks, wherein top surfaces of the lower electrodes are exposed upon removal of the two-dimensional array of sacrificial pillar structures; and
forming a layer of nucleation inhibitor molecules on physically exposed surfaces of the dielectric matrix layer while suppressing adhesion of the nucleation inhibitor molecules on the top surfaces of the lower electrodes.

14. The method of claim 13, wherein at least a portion of the selector elements is formed by performing a selective deposition process that deposits a selector material of the selector elements on the top surfaces of the lower electrodes while suppressing nucleation of the selector material over the layer of nucleation inhibitor molecules.

15. The method of claim 14, wherein the selective deposition process further comprises a precursor adhesion step in which at least one monolayer of ovonic threshold switch material is adsorbed to the top surfaces of the lower electrodes while adhesion the ovonic threshold switch material on the layer of nucleation inhibitor molecules is suppressed.

16. The method of claim 15, wherein the selective deposition process further comprises an oxygen plasma treatment step that removes ligands from the at least one monolayer of the ovonic threshold switch material and removes the layer of nucleation inhibitor molecules.

17. The method of claim 1, wherein the selector elements comprise portions of an ovonic threshold switch material that is deposited by physical vapor deposition.

18. A magnetoresistive memory array, comprising:
a one-dimensional array of first conductive lines laterally extending along a first horizontal direction;
an array of magnetic tunnel junction stacks each comprising reference layer, a tunnel barrier layer, at least one free layer overlying the one-dimensional array of first conductive lines;
a two-dimensional array of lower electrodes overlying the array of magnetic tunnel junction stacks;
an array of selector elements overlying the two-dimensional array of lower electrodes, wherein each of the selector elements has a vertical sidewall having a bottom periphery that coincides with a top periphery of a tapered sidewall of an underlying lower electrode of the two-dimensional array of lower electrodes;
a dielectric matrix layer laterally surrounding the two-dimensional array of selector elements and the two-dimensional array of lower electrodes; and
a one-dimensional array of second conductive lines laterally extending along a second horizontal direction and contacting at least one selector element within the array of selector elements.

19. The magnetoresistive memory array of claim 18, wherein each selector element within the array of selector elements comprises:
a horizontally-extending portion that extends along the second horizontal direction; and
a one-dimensional array of pillar portions adjoined to a bottom surface of the horizontally-extending portion and overlying a respective one of the lower electrodes.

20. The nonmagnetic memory array of claim 18, wherein each of the magnetic tunnel junction stacks comprises one reference layer, and a plurality of free layers that are arranged along the first horizontal direction and overlying said one reference layer.
